(19) United States
(12) Patent Application Publication
(10) Pub. No.: US 2026/0032824 A1
(43) Pub. Date: Jan. 29, 2026

(54) PCB COMPONENT AND METHOD FOR MANUFACTURING VOLTAGE REGULATOR MODULE

(71) Applicant: Delta Electronics, Inc., Taoyuan City (TW)

(72) Inventors: Xueliang Chang, Shanghai (CN); Xingxin Zheng, Shanghai (CN); Jie Xu, Shanghai (CN); Kun Jiang, Shanghai (CN)

(21) Appl. No.: 19/260,385

(22) Filed: Jul. 4, 2025

(30) Foreign Application Priority Data
Jul. 26, 2024 (CN) 202411016674.0
Mar. 31, 2025 (CN) 202510390590.1

(51) Int. Cl. H05K 1/18; H05K 1/14; H05K 3/36

(52) U.S. Cl. CPC H05K 1/185; H05K 1/144; H05K 3/368; H05K 2201/041; H05K 2201/1003; H05K 2201/10515

(57) ABSTRACT

A PCB component used in a voltage regulator module and a method for manufacturing the voltage regulator module are disclosed. The PCB component includes a PCB and an inductor. The PCB includes a top surface and a bottom surface. The inductor includes a magnetic core and a winding. The winding runs through the magnetic core, and the winding forms an upper outlet terminal on the upper surface and a lower outlet terminal on the lower surface. The inductor is embedded in the PCB. A plurality of conductive layers are respectively disposed above the upper surface and below the lower surface. The upper outlet terminal and the lower outlet terminal are electrically connected to a power device and an external circuit board. The power device, the PCB component and the external circuit board are stacked vertically in sequence and connected through one reflow welding process to form a voltage regulator module.

### CROSS-REFERENCE TO RELATED APPLICATION

This application claims priority to China Patent Application No. 202411016674.0, filed on Jul. 26, 2024, and China Patent Application No. 202510390590.1, filed on Mar. 31, 2025. The entire contents of the above-mentioned patent applications are incorporated herein by reference for all purposes.

### FIELD OF THE INVENTION

The present disclosure relates to an assembly structure of an electronic device, and more particularly to, a PCB component used in a voltage regulator module and a method for manufacturing the voltage regulator module.

### BACKGROUND OF THE INVENTION

With the rapid development of artificial intelligence, the current of computing chips has increased rapidly and exceeded 1000 amperes. This poses a huge challenge to the voltage regulator that powers the chip.

### SUMMARY OF THE INVENTION

An object of the present disclosure is to provide a PCB component used in a voltage regulator module and a method for manufacturing the voltage regulator module. By integrating an inductor, an input circuit path, a control signal path, a signal detection path and a test function circuit into a PCB component, the number of stacked layers of the voltage regulator module is simplified. Thereby, the total number of welding times of the product is greatly reduced, the production cost of the voltage regulator module is reduced, and the product quality is improved. One layer of the voltage regulator module is a PCB component with an embedded inductor, and the layer above the PCB component can be used to place the power device. In the inductor integrated in the PCB component, the inductor winding runs through the inside of the magnetic core and is embedded in the PCB component. The two output terminals of the inductor winding are integrated with the circuit-board copper in the PCB component through the electroplating process. The electroplated copper is interconnected from the inside to the outside, and pressed together successively to form the welding position for the IC power device on the outer layer of the PCB component. The number of electroplated copper layers stacked on both sides of the inductor is symmetrical and equal. Since the power device, the PCB component, the stacked component and the external circuit board are connected in an up-and-down stacking manner, it facilitates to reduce the total occupied area of the voltage regulator module. At the same time, the welding of the entire voltage regulator can be completed with only one reflow welding, so that the module production yield is increased and the production cost is reduced. At the same time, the PCB component can coordinate with the power devices, external circuit boards and stacked parts to adjust the placement order when stacking, so that the voltage regulator module can be flexibly adjusted according to actual conditions during manufacturing, which is easy to manufacture. Furthermore, the PCB component, the power device, the external circuit board and the stacked component are coordinated with each other and allowed adjusting the placement order when stacking, so that the manufacturing process of the voltage regulator module is flexibly adjustable according to the practical conditions, and it is easy to manufacture. On the other hand, when the PCB component is used in the manufacture of the voltage regulator module, it can further combine a contiguous structure of multiple PCB components and a substrate structure of multiple external circuit boards. In that, multiple voltage regulator modules can be manufactured with only one reflow welding process. After cutting and separation, a plurality of voltage regulator modules are obtained and independent with each other. Thereby the product quality and the long-term reliability are improved, and the production costs are greatly reduced. Alternatively, by placing the multiple PCB components on an assembling jig, the multiple voltage regulator modules can be manufactured with only one reflow welding process.

In accordance with an aspect of the present disclosure, a PCB component is provided and includes a PCB and an inductor. The PCB includes a top surface and a bottom surface opposite to each other. The inductor includes an upper surface and a lower surface opposite to each other. The inductor further includes a magnetic core and a winding. The winding runs through the magnetic core, and the winding forms an upper outlet terminal on the upper surface and a lower outlet terminal on the lower surface. The inductor is embedded in the PCB, the top surface is spatially corresponding to the upper surface, the bottom surface is spatially corresponding to the lower surface, a plurality of conductive layers are respectively disposed above the upper surface and below the lower surface, an upper welding position is disposed on the top surface and electrically connected to the upper outlet terminal, and a lower welding position is disposed on the bottom surface and electrically connected to the lower outlet terminal. The upper welding position is electrically connected to a power device and configured to transmit an input electrical signal, the lower welding position is electrically connected to an external circuit board and configured to transmit an output electrical signal, and the power device, the PCB component and the external circuit board are stacked vertically in sequence. Electrical connections between the power device and the upper welding position, and between the lower welding position and the external circuit board are implemented through one reflow welding process to form a voltage regulator module.

In accordance with another aspect of the present disclosure, a method for manufacturing the voltage regulator module is provided and includes steps of: (a) providing a PCB component, wherein the PCB component includes a PCB and an inductor, wherein the PCB includes a top surface and a bottom surface opposite to each other, the inductor includes an upper surface and a lower surface opposite to each other, the top surface is spatially corresponding to the upper surface, the bottom surface is spatially corresponding to the lower surface, the inductor is embedded in the PCB, the inductor includes a magnetic core and a winding, the winding runs through the magnetic core, and the winding forms an upper outlet terminal on the upper surface and a lower outlet terminal on the lower surface, wherein a plurality of conductive layers are respectively disposed above the upper surface and below the lower surface, an upper welding position is disposed on the top surface and electrically connected to the upper outlet terminal, and a lower welding position is disposed on the bottom surface and electrically connected to the lower outlet terminal; (b) providing a power device, including a welding portion spatially corresponding to the upper welding position; (c) providing an external circuit board, including a welding region spatially corresponding to the lower welding position; (d) placing a solder on the welding region and the upper welding position, and stacking the power device, the PCB component and the external circuit board in sequence vertically, wherein the welding portion is aligned to the upper welding position, and the lower welding position is aligned to the welding region; and (e) performing one reflow welding process to achieve electrical connections between the power device and the PCB component and between the PCB component and the external circuit board.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a structural perspective view illustrating a horizontal voltage regulator module according to the prior art;

FIG. 2 is a structural perspective view illustrating a stacked voltage regulator module according to the prior art;

FIG. 3 is structural perspective view illustrating a voltage regulator module (without an external circuit board) according to a first embodiment of the present disclosure;

FIG. 4 is a cross-sectional view taken along the line AA′ of FIG. 3;

FIG. 5 is a cross-sectional view illustrating the PCB component according to the first embodiment of the present disclosure;

FIG. 6 is structural perspective view illustrating the inductor according to the first embodiment of the present disclosure;

FIG. 7 is a schematic diagram illustrating the upper welding position on the top surface of the PCB component corresponding to the power device according to the first embodiment of the present disclosure;

FIG. 8 is a schematic diagram illustrating the lower welding position on the bottom surface of the PCB component according to the first embodiment of the present disclosure;

FIG. 9 is a schematic diagram illustrating the lower welding position on the bottom surface of the PCB component according to a second embodiment of the present disclosure;

FIG. 10 and FIG. 11 are schematic diagrams illustrating a voltage regulator module with an external circuit board disassembled according to the second embodiment of the present disclosure;

FIG. 12 and FIG. 13 are exploded structural views illustrating the voltage regulator module according to the second embodiment of the present disclosure;

FIG. 14 is a flow chart illustrating a method for manufacturing the voltage regulator module according to an embodiment of the present disclosure;

FIG. 15 is a schematic diagram illustrating a PCB component according to another embodiment of the present disclosure;

FIG. 16 is a schematic diagram illustrating a plurality of PCB components combined to form a contiguous structure according to an embodiment of the present disclosure;

FIG. 17 is a structural perspective view illustrating a voltage regulator module with a stacked component according to a third embodiment of the present disclosure;

FIG. 18 and FIG. 19 are exploded structural views illustrating the voltage regulator module according to the third embodiment of the present disclosure; and

FIG. 20 is a cross-sectional view illustrating the stacked component according to the third embodiment of the present disclosure.

### DETAILED DESCRIPTION

The present disclosure will now be described more specifically with reference to the following embodiments. It is to be noted that the following descriptions of embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed. Further, spatially relative terms, such as “upper,” “lower,” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second,” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items.

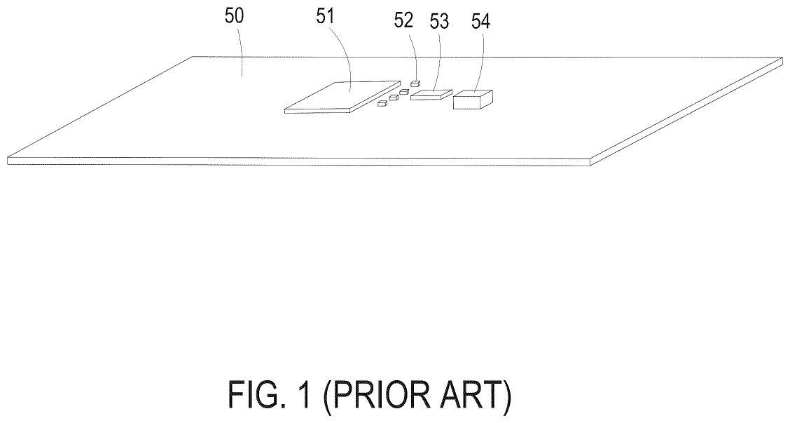

Generally, the voltage regulators have the characteristics of outputting low voltage and high current, and are mainly completed by buck circuits. The Buck circuit mainly includes an IC (Integrated Circuit) power device, a power inductor and an input and output capacitor. In a conventional horizontal voltage regulator module, as shown in FIG. 1, a general motherboard manufacturer will horizontally arrange an input capacitor 52, an IC power device 53 and a power inductor 54 on a motherboard 50, next to a calculation chip 51. An output capacitor (not shown in the figure) is mainly arranged below the calculation chip 51. The horizontal connection method of the voltage regulator will increase the total area of consumption. Moreover, as the wiring length is increased, the line parasitic parameters and the losses are increased accordingly, so that the conversion efficiency of the power supply is affected. Based on this factor, the power supply manufacturer will design the on-board voltage regulator composed of discrete components as a voltage regulator module to improve power density and efficiency. This voltage regulator module is directly used by the motherboard manufacturer and placed around the calculation chip, so that the output current of the voltage regulator is greatly increased in a limited space and the power supply meets the requirements of the higher power calculation chip.

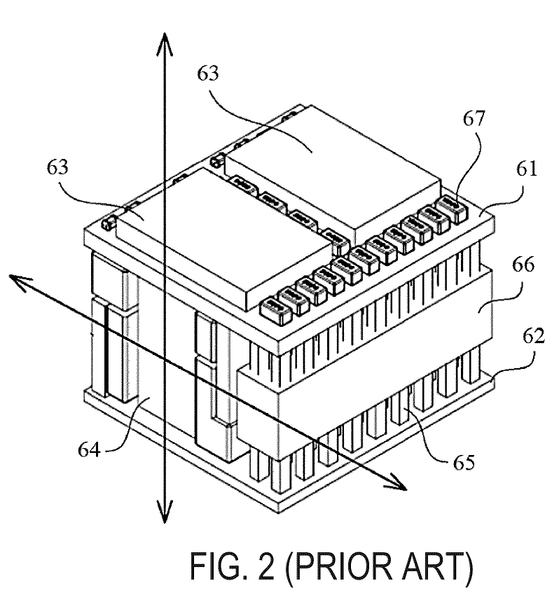

Another typical stacked voltage regulator module is shown in FIG. 2. The structure includes an IC power device 63 and an inductor 64 stocked up and down, and jointly soldered on an identical printed circuit board (PCB) 61. Moreover, a capacitor 67 is further disposed on the PCB 61. In addition, the inductor 64 is disposed on another PCB 62. The PCB 62 is used for electrical signal transfer, so that the welding surface of the voltage regulator module matches the welding surface of the calculation main board (not shown in the figure). The PCB 61 and the PCB 62 are electrically connected by a plurality of signal connectors 65, and the plurality of signal connectors 65 are connected by a connector 66. However, such voltage regulator module is a four-layer structure. The main body of the voltage regulator module has been reflowed and soldered multiple times, so that the difficulty and the production cost are increased. Moreover, the voltage regulator module needs to undergo an additional reflow welding on the computer motherboard. The quality and the long-term reliability of the voltage regulator are greatly affected by such numerous welding processes.

In view of this, there is a need of providing a PCB component used in a voltage regulator module and a method for manufacturing the voltage regulator module. Multiple PCB components including output inductors and signal connectors are integrated, so that the number of components is greatly reduced and the number of stacking layers of the voltage regulator module is simplified. Thereby the total number of welding times of the product is greatly reduced, the production cost of the voltage regulator module is reduced, and the product quality is improved. The PCB component can be placed in a stacked order with the power device, the external circuit board and the stacked component, so that the voltage regulator module can be flexibly adjusted according to the practical conditions during manufacturing. It is easy to manufacture, and the welding of the entire voltage regulator module can be completed by one reflow welding, so that the module production yield is increased and the production cost is reduced. Furthermore, when the PCB component is used in the manufacture of the voltage regulator module, it can further combine a contiguous structure of multiple PCB components and a substrate structure of multiple external circuit boards. In that, multiple voltage regulator modules can be manufactured with only one reflow welding process. After cutting and separation, a plurality of voltage regulator modules are obtained and independent with each other. Thereby the product quality and the long-term reliability are improved, and the production costs are greatly reduced. Alternatively, by placing the multiple PCB components on an assembling jig, the multiple voltage regulator modules can be manufactured with only one reflow welding process.

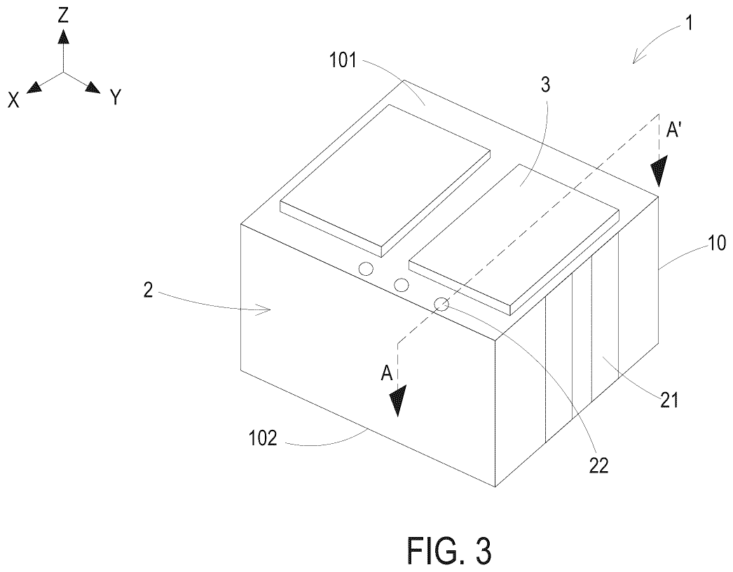

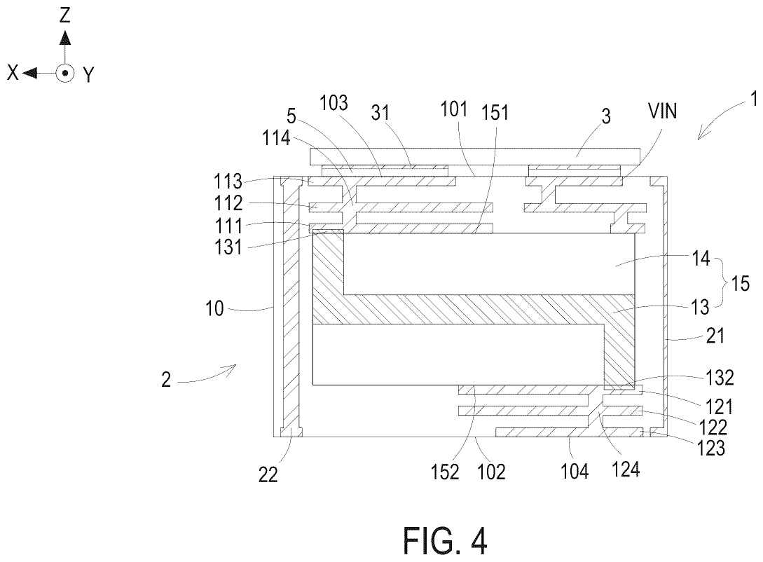

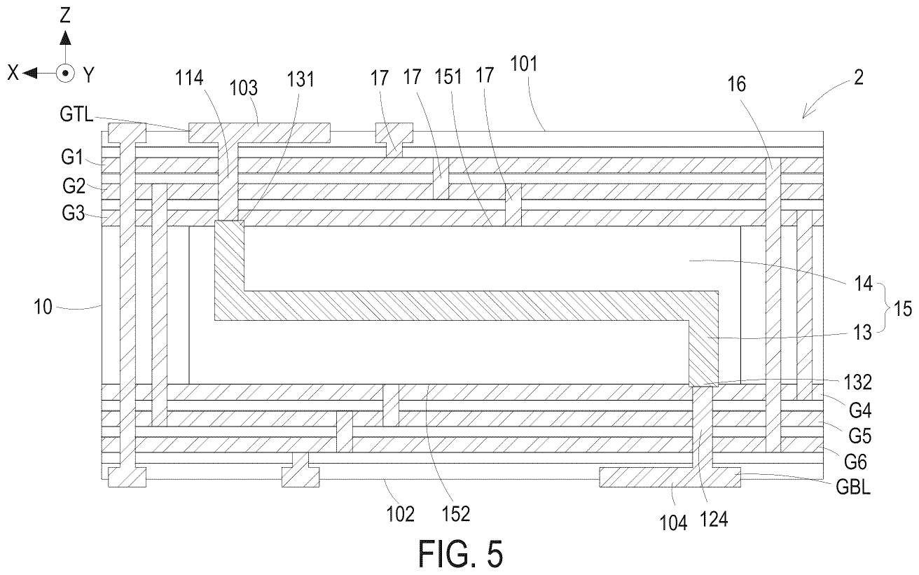

FIG. 3 is structural perspective view illustrating a voltage regulator module (without an external circuit board) according to a first embodiment of the present disclosure. FIG. 4 is a cross-sectional view taken along the line AA′ of FIG. 3. FIG. 5 is a cross-sectional view illustrating the PCB component according to the first embodiment of the present disclosure. For ease of illustration, an external circuit board is not shown in FIG. 3 and FIG. 4. In order to simplify the number of component layers of the voltage regulator module 1, facilitate the subsequent welding process and reduce the number of welding times, the present disclosure provides a PCB component 2 used in a voltage regulator module 1. The PCB component 2 includes a PCB 10 and an inductor 15. The PCB 10 includes a top surface 101 and a bottom surface 102 opposite to each other. The inductor 15 is embedded in the PCB 10. The inductor 15 includes an upper surface 151 and a lower surface 152 opposite to each other. The inductor 15 further includes a magnetic core 14 and a winding 13. The winding 13 runs through the magnetic core 14, and the winding 13 forms an upper outlet terminal 131 on the upper surface 151 and a lower outlet terminal 132 on the lower surface 152. Notably, in the embodiment, a volume proportion of the magnetic core 14 in the PCB component 2 exceeds 50%. Furthermore, in the embodiment, the PCB 10 includes a plurality of conductive layers. In the embodiment, the PCB 10 includes M conductive layers and N conductive layers. The M conductive layers are arranged above the upper surface 151 of the inductor 15. In the embodiment, the M conductive layers includes three conductive layers 111, 112, 113. The upper outlet terminal 131 of the winding 13 is electrically connected to the inner conductive layer 111 of the M conductive layers attached to the upper surface 151 of the inductor 15. The upper conductive layer 113 forms an upper welding position 103 disposed on the top surface 101 of the PCB component 2. In the embodiment, the upper welding position 103 and the upper outlet terminal 131 of the winding 13 are spatially corresponding to each other and electrically connected through an upper circuit channel 114. The upper circuit channel 114 is electrically connected to the upper welding position 103 and the upper outlet terminal 131 through copper-electroplated holes in the M conductive layers from the inside to the outside. In the embodiment, the N conductive layers are arranged below the lower surface 152 of the inductor 15. In the embodiment, the N conductive layers include three conductive layers 121, 122, 123. The lower outlet terminal 132 is electrically connected to the inner conductive layer 121 of the N conductive layers attached to the lower surface 152 of the inductor 15. The lower conductive layer 123 forms a lower welding position 104 disposed on the bottom surface 102 of the PCB component 2. In the embodiment, the lower welding position 104 and the lower outlet terminal 132 of the winding 13 are spatially corresponding to each other and electrically connected through a lower circuit channel 124. The lower circuit channel 124 is electrically connected to the lower welding position 104 and the lower outlet terminal 132 through copper-electroplated holes in the N conductive layers from the inside to the outside. Notably, M and N are positive integers, and M=N≥2.

In the embodiment, the upper welding position 103 on the top surface 101 of the PCB 10 is electrically connected to a welding pad 31 of a power device 3 and configured to transmit an input electrical signal. In some embodiments, the power device 3 is an integrated circuit (IC) device. The electrical connection between the welding pad 31 and the upper welding position 103 is implemented by using a solder 5 in a reflow welding process. In the embodiment, the novel voltage regulator module 1 includes the PCB component 2, the power device 3 and the external circuit board (not shown in the figure). The overall structure of the voltage regulator module 1 is shown in FIG. 3, and includes three parts: the upper power device 3, the lower PCB component 2, and the bottom external circuit board (not shown). In some embodiments, the power device 3 is a DrMOS, including two switch tubes and one driving circuit. The PCB component 2 used to construct the voltage regulator module 1 structure can further form a board-edge copper-plating layer 21 through a board-edge copper-plating process. In the embodiment, the board-edge copper-plating layer 21 is disposed on the top surface 101, the bottom surface 102 and one side wall of the PCB 10, electrically connected between the M conductive layers and the N conductive layers, and configured to transmit current signals or form a test function circuit. In other embodiments, the board-edge copper-plating layer 21 is further connected to other subsequent mainboards for testing and maintenance. In another embodiment, the PCB component 2 further includes a conductive through hole 22. The conductive through hole 22 runs through the top surface 101 and the bottom surface 102 of the PCB 10 and is electrically connected between the M conductive layers and the N conductive layers. In some embodiments of the present disclosure, each adjacent two of the M conductive layers and the N conductive layers are connected via a buried via 17, and the M conductive layers and the N conductive layers are electrically connected to an external electrical signal from the inside to the outside through the buried via 17 sequentially.

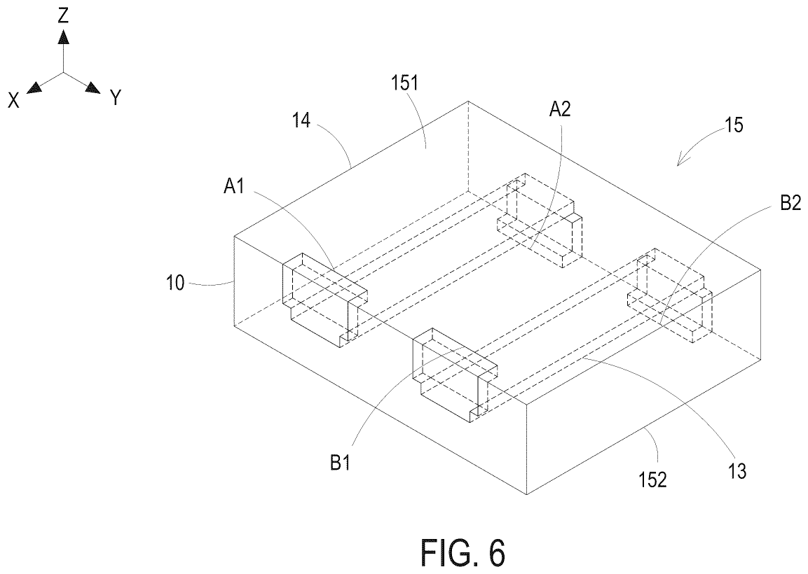

FIG. 6 is structural perspective view illustrating the inductor according to the first embodiment of the present disclosure. Please refer to FIG. 3 to FIG. 6. In the embodiment, the PCB component 2 includes an inductor 15 embedded in the PCB 10, and a multilayer board structure above the upper surface 151 and below the lower surface 152 of the inductor 15. The inductor 15 has an integrated structure as shown in FIG. 6. In some embodiments, the inductor 15 includes at least one winding 13 and a magnetic core 14. The winding 13 runs through the magnetic core 14 made of a magnetic conductive material such as ferrite or magnetic powder core, and then the winding 13 and the magnetic core 14 are pressed together to form the integrated inductor 15, so that the entire process is integrated. Notably, in the embodiment, a volume of the magnetic core 14 in the PCB component 2 exceeds 50%, and a projected area of the magnetic core 14 on the top view of the PCB component 2 (i.e., the horizontal plane formed by the direction X and the direction Y in FIG. 6) exceeds more than 70% of the PCB component 2. By increasing the effective magnetic conductive cross-sectional area of the magnetic core 14, the loss of the magnetic core 14 and the loss of the winding 13 are reduced, so that the overall conversion efficiency of the voltage regulator module 1 is improved. In other words, in a horizontal plane, parallel to the upper surface 151 and the lower surface 152, the projection area of the magnetic core 14 exceeds more than 70% of the projection area of the PCB component 2.

In the embodiment, the inductor 15 includes two windings 13. The two windings 13 form two upper outlet terminals A1, B1 respectively on the upper surface 151 of the inductor 15, and two lower outlet terminals A2, B2 respectively on the lower surface 152 of the inductor 15, as shown in FIG. 6.

In the embodiment, as shown in FIG. 5, the M conductive layers include inner conductive layers G1, G2, G3 and a top surface conductive layer GTL. The N conductive layers include inner conductive layers G4, G5, G6 and a bottom surface conductive layer GBL. In the embodiment, the inner conductive layers G1, G2, G3, G4, G5, G6 are regarded as inner layers of the PCB component 2, and are used for internal wiring and copper cladding of the PCB component 2. The top surface conductive layer GTL and the bottom surface conductive layer GBL are regarded as the outer surface layer of the PCB component 2, such as the top surface 101 and the bottom surface 102 of the PCB 10, which are used for surface wiring, copper cladding and device welding.

In the embodiment, the inductor 15 is integrated in the PCB component 2. The PCB component 2 further includes an input circuit path, a control signal path, a signal detection path, or a test function circuit integrated therein. The wiring lines in the multi-layer board structure of PCB 10 are used to realize the transmission of input signals, control signals and sampling signals. In one embodiment, the entire PCB component of the voltage regulator module 1 further includes a board-edge copper-plating layer 21 for adding functions. For example, the board-edge copper-plating layer 21 is used to transmit current signals or form a test function circuit. Certainly, the present disclosure is not limited thereto.

In the embodiment, the power input terminal VIN is connected to the power device 3 via the upper surface conductive layer GTL of the PCB component 2. The welding pad 31 of the power device 3 is spatially corresponding to the upper welding position 103 on the upper surface of the PCB component 2. The upper welding position 103 and the upper outlet terminal 131 of the inductor 15 are spatially corresponding to each other and electrically connected through the upper circuit channel 114. The upper welding position 103 is connected to the upper outlet terminal 131 on the upper surface 151 of the inductor 15 by electroplating drilling, so as to realize the electrical signal transmission between the power device 3 and the inductor 15. Similarly, the lower outlet terminal 132 on the lower surface 152 of the inductor 15 is electrically connected to the welding pad connected to the lower surface conductive layer GBL of the PCB component 2 by electroplating drilling.

In other embodiments, the control signal and the sampling signal are electrically connected between the welding pads on the top surface 101 and the bottom surface 102 by means of internal wiring of the PCB component 2 and electroplating drilling. In addition, the electrical connection between the welding pads on the top surface 101 and the bottom surface 102 of the PCB component 2 can also be achieved through the board-edge copper-plating layer 21. At the same time, the load current can flow from the bottom surface 102 of the PCB component 2 back to the top surface 101 of the PCB component 2 through the board-edge copper-plated layer 21. Since the transmission path is exposed on the outer surface of the PCB component 2, it is beneficial to the overall heat dissipation of the PCB component 2.

In the embodiment, the inductor 15 is embedded in the PCB multilayer structure, and the upper outlet terminal 131 of the winding 13 is connected to the inner conductive layer G3, which can be achieved by electroplating. In one embodiment, the plurality of conductive layers above the inductor upper surface 151 are electrically connected to each other. In some embodiments, the inner conductive layers G3, G2, G1 and the top surface conductive layer GTL are connected in sequence through a copper electroplating process, and electrically connected through the upper circuit channel 114. Similarly, the plurality of conductive layers below the inductor bottom surface 152 are electrically connected to each other. In some embodiments, the inner conductive layers G4, G5, G6 and the bottom surface conductive layer GBL are connected in sequence through a copper electroplating process, and electrically connected through the lower circuit channel 124.

In the embodiment, a metal conductor 16 is further disposed inside the PCB component 2, and the metal conductor 16 is configured to transmit an electrical signal. In other embodiments, the metal conductor is a copper block for transmitting control signals or other signals, and the copper block is helpful for improving the stress in the PCB component 2. Certainly, the arrangement of the copper block is adjustable according to the practical.

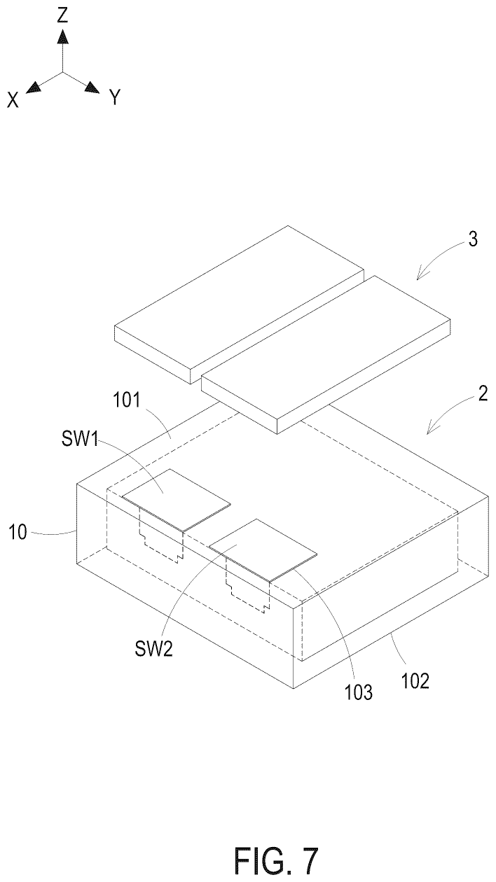

FIG. 7 is a schematic diagram illustrating the upper welding position on the top surface of the PCB component corresponding to the power device according to the first embodiment of the present disclosure. In the embodiment, the upper multi-layer board structures are processed layer by layer from the inside to the outside through a copper electroplating process, and stacked in sequence to form the upper welding position 103 on the top surface 101 of the PCB component 2. Finally, the upper surface conductive layer GTL forms a first winding upper welding position SW1 and a second winding upper welding position SW2 corresponding to the two power devices 3 on the top surface 101 of the PCB component 2. As shown in FIG. 7. the first winding upper welding position SW1 and the second winding upper welding position SW2 are used to weld the power devices 3, so that the external input current flows into the inductor 15. The terminals of the inductor 15 are located inside the PCB component 2 and directly connected through electroplating and wiring, so that the risks of welding the traditional independent inductor and PCB are avoided, and the process flow is reduced. In the embodiment, the PCB component 2 is paired with two power devices 3. In other embodiments, the PCB component 2 is matched with a number of power devices 3 according to the practical requirements. If the voltage regulator module 1 needs to construct a plurality of power devices 3 on the PCB component 2, the power devices 3 can be arranged horizontally on the top surface 101 of the PCB component 2 and electrically connected to the inductor 15 through the upper welding position 103.

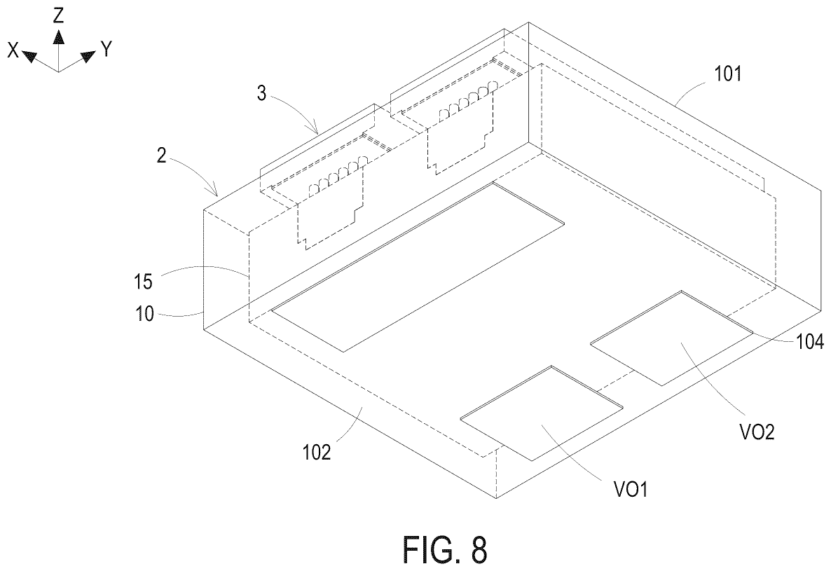

FIG. 8 is a schematic diagram illustrating the lower welding position on the bottom surface of the PCB component according to the first embodiment of the present disclosure. Similarly, the lower multi-layer board structures below the inductor lower surface 152 are processed layer by layer from the inside to the outside through a copper electroplating process, and stacked in sequence to form the lower welding position 104 on the bottom surface 102 of the PCB component 2. The output terminals A2, B2 (refer to FIG. 6) on the other side of the inductor 15 are connected to the lower surface conductive layer GBL layer by layer through electroplating, and form a first output welding position VO1 and a second output welding position VO2, as shown in FIG. 8. In one embodiment, the first output welding position VO1 and the second output welding position VO2 are used to connect to an external circuit board such as a system motherboard or an adapter board, so that the current flows out of the inductor to power the system motherboard or provide the electrical signals to the adapter board. Notably, the multilayer board structures above the upper surface 151 and below the lower surface 152 of the inductor 15 have the same number of conductive layers and are symmetrically arranged to ensure that the electrical performance of both sides of the inductor 15 is the same.

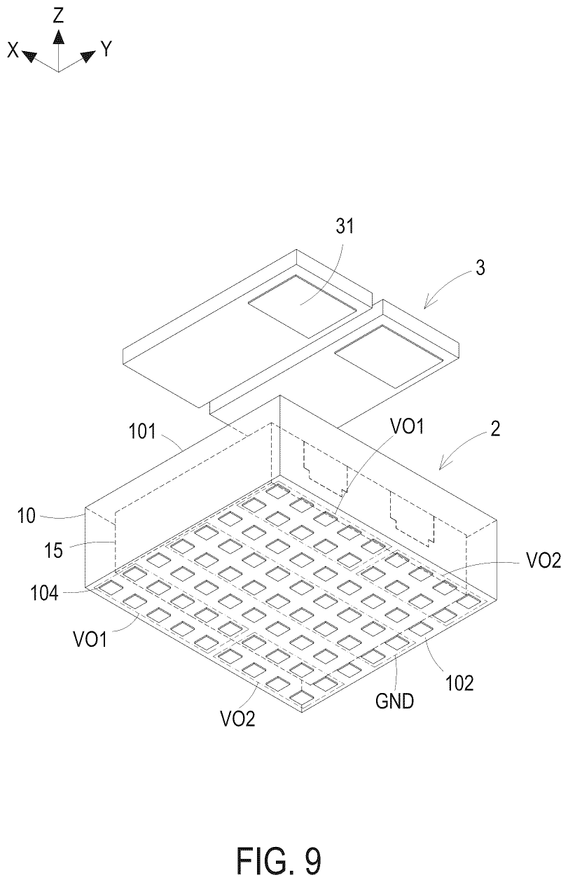

FIG. 9 is a schematic diagram illustrating the lower welding position on the bottom surface of the PCB component according to a second embodiment of the present disclosure. In this embodiment, the lower welding position 104 formed by electroplating on the bottom surface 102 of the PCB component 2 is adjustable according to the practical requirements. In the embodiment, the lower welding position 104 forms matrix of pads. The first output welding positions VO1 and the second output welding positions VO2 respectively include different square array pads, and other square array pads can be used as ground welding positions GND. In some embodiments of the present disclosure, the multilayer board structure below the lower surface 152 of the inductor 15 is processed layer by layer from the inside to the outside to form the first output welding positions VO1, the second output welding positions VO2 and the ground welding positions GND. The first output welding positions VO1 and the ground welding positions GND are arranged alternately, and the second output welding positions VO2 and the ground welding positions GND are arranged alternately, so as to disperse the current density of the PCB component 2 and the external circuit board and reduce the parasitic inductance of the output port.

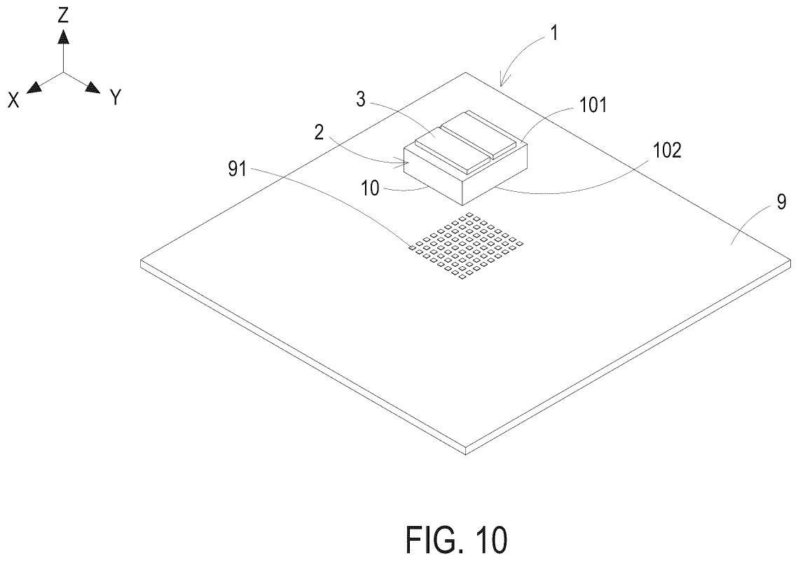

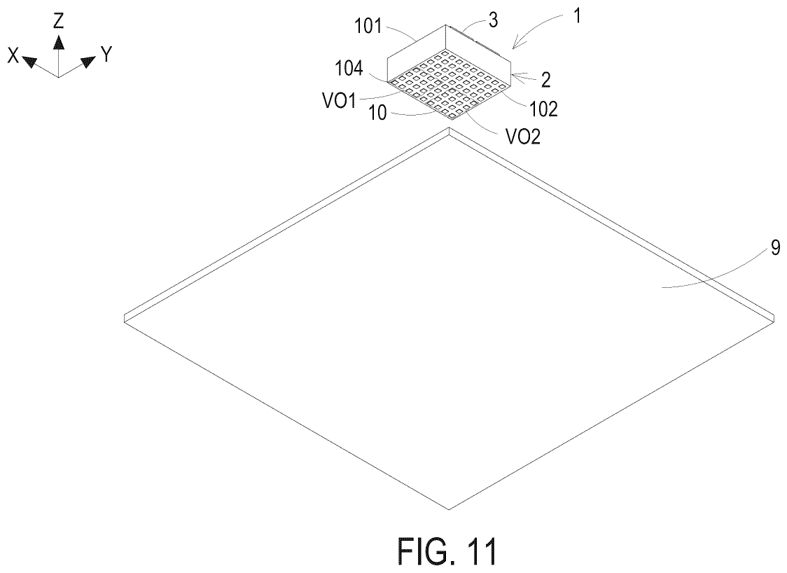

FIG. 10 and FIG. 11 are schematic diagrams illustrating a voltage regulator module with an external circuit board disassembled according to the second embodiment of the present disclosure. In this embodiment, the lower PCB component 2 is combined with the upper power device 3 and disposed on an external circuit board 9 to form the voltage regulator module 1. In some embodiments, the bottom surface 102 of the lower PCB component 2 is electrically connected to the external circuit board 9. In the embodiment, the external circuit board 9 is, for example, a motherboard or an adapter board of an external system. The bottom surface 102 of the PCB component 2 has lower welding positions 104 including a plurality of matrix pads. Part of the matrix pads are further divided into a first output welding position VO1 and a second output welding position VO2 according to the circuit design requirements, and the other part of matrix pads are classified into other applications. Moreover, the external circuit board 9 includes a welding region 91 disposed on the upper surface and corresponding to the matrix pads. In the embodiment, the electrical connection between the welding region 91 of the external circuit board 9 and the lower welding position 104 of the PCB component 2 is implemented through a reflow welding process. In the embodiment, the terminals of the inductor 15 are all integrally formed inside the PCB component 2, and electrically connected directly through the electroplating and wiring of the multilayer board structure above the upper surface 151 and below the lower surface 152 of the inductor 15, so that the risks of welding the independent inductors and the external system are avoided, and the process flow is reduced.

Notably, when the voltage regulator module 1 of the present disclosure is assembled before welding, the power device 3, the PCB component 2 and the external circuit board 9 are vertically stacked in sequence. The upper welding position 103 of the PCB component 2 is electrically connected to the power device 3 to transmit the input electrical signal. The lower welding position 104 of the PCB component 2 is electrically connected to the external circuit board 9 to transmit and output electrical signals. Notably, the electrical connections between the power device 3 and the upper welding position 103 and between the lower welding position 104 and the external circuit board 9 are electrically connected through one single reflow welding process to form the voltage regulator module 1. In other words, multiple welding steps are avoided in the manufacturing of the voltage regulator module 1 of the present disclosure. If the welding joints undergo multiple reflow high-temperature processes, the bubbles inside the welding joints are more likely to gather and expand. Moreover, it causes solder beads to splash out and causes the welding quality problems. Especially on artificial intelligence motherboards, the number of voltage regulator modules 1 used is dozens or hundreds, and the quality risk will be amplified seriously. In order to make the PCB component 2 and the power device 3 go through only one reflow welding process when completing the production of the voltage regulator, the present disclosure further provides a new method. The power device 3, the PCB component 2 and the external circuit board 9 are stacked vertically. Thereafter, the welding of the entire power system can be completed through one single reflow welding process. Thereby, the overall mechanical structure of the voltage regulator module 1 is maintained, all the performance advantages are retained, the product quality and long-term reliability are improved, and the overall cost is reduced.

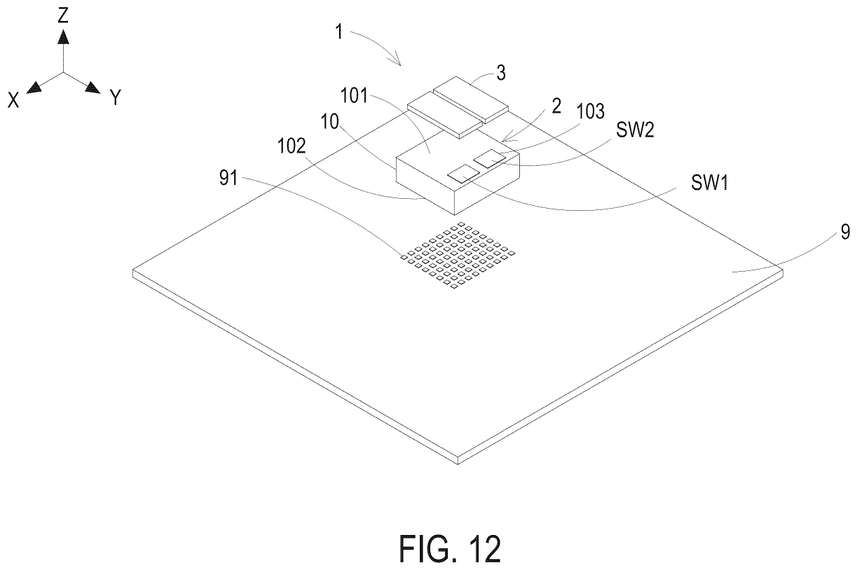

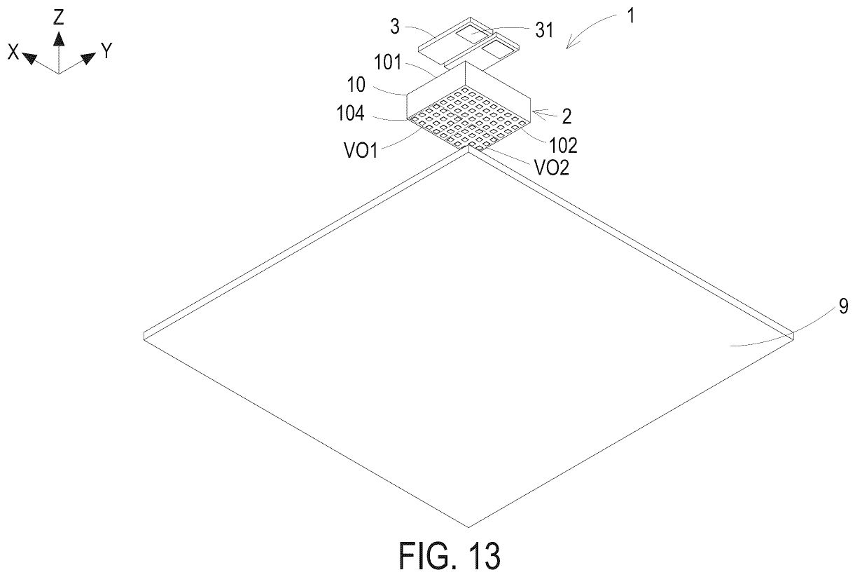

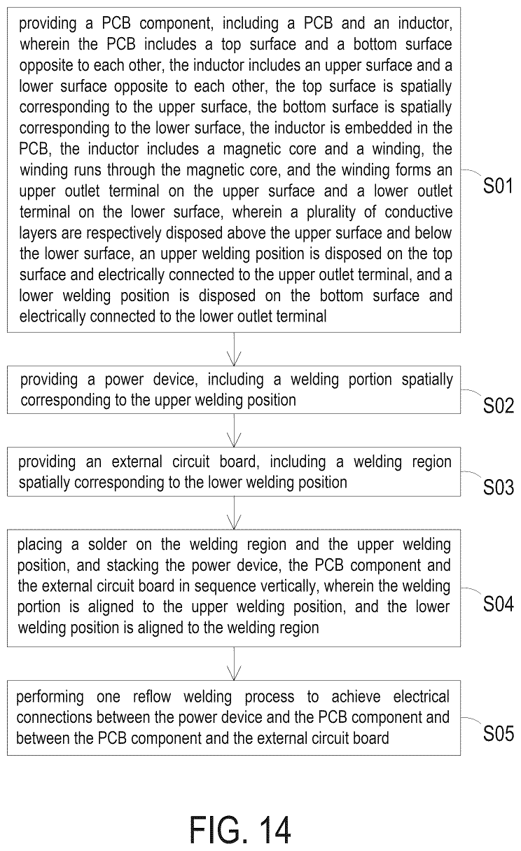

FIG. 12 and FIG. 13 are exploded structural views illustrating the voltage regulator module according to the second embodiment of the present disclosure. FIG. 14 is a flow chart illustrating a method for manufacturing the voltage regulator module according to an embodiment of the present disclosure. A method for manufacturing the voltage regulator module through once reflow welding is provided. Please refer to FIG. 3 to FIG. 14. In the embodiment, first, as shown in steps S01, S02, S03, a PCB component 2, a power device 3 and an external circuit board 9 are provided respectively, and the providing sequence is adjustable according to the practical requirements. The PCB 10 includes a top surface 101 and a bottom surface 102 opposite to each other. The inductor 15 is embedded in the PCB 10. The inductor 15 includes an upper surface 151 and a lower surface 152 opposite to each other. The inductor 15 further includes a magnetic core 14 and a winding 13. The winding 13 runs through the magnetic core 14, and the winding 13 forms an upper outlet terminal 131 on the upper surface 151 and a lower outlet terminal 132 on the lower surface 152. Furthermore, in the embodiment, the PCB 10 includes a plurality of conductive layers. In some embodiments, the PCB 10 includes M conductive layers and N conductive layers. The M conductive layers are arranged above the upper surface 151 of the inductor 15, and the N conductive layers are arranged below the lower surface 152 of the inductor 15. Notably, there are the same number of conductive layers above the upper surface 151 and below the lower surface 152. An upper welding position 103 is disposed on the top surface 101 of the PCB component 2 and electrically connected to the upper outlet terminal 131 of the winding 13, and a lower welding position 104 is disposed on the bottom surface 102 of the PCB component 2 and electrically connected to the lower outlet terminal 132 of the winding 13. Furthermore, in the embodiment, a volume of the magnetic core 14 in the PCB component 2 exceeds 50%, and a projected area of the magnetic core 14 on the top view of the PCB component 2 exceeds more than 70% of the PCB component 2, so that the loss of the magnetic core 14 and the loss of the winding 13 are reduced, and the overall conversion efficiency of the voltage regulator module 1 is improved. In other words, in a horizontal plane, parallel to the upper surface 151 and the lower surface 152, the projection area of the magnetic core 14 exceeds more than 70% of the projection area of the PCB component 2. In the embodiment, the power device 3 is an integrated circuit (IC) device. In the embodiment, the power device 3 is a DrMOS, including two switch tubes and one driving circuit. The power device 3 includes two surfaces, and the lower surface includes a welding portion formed by the welding pad 31, which is spatially corresponding to the upper welding position 103 of the PCB component 2. In the embodiment, the upper surface of the external circuit board 9 includes a welding region 91 with a solder pad structure, which is spatially corresponding to the lower welding position 104 of the PCB component 2 and used for welding the PCB component 2. Thereafter, as shown in a step S04, a solder is placed on the welding region 91 of the external circuit board 9 and the upper welding position 103 of the PCB component 2. In some embodiments, the solder is a solder paste, and the solder is applied by spraying or printing. In the step, the power device 3, the PCB component 2 and the external circuit board 9 with the solder placed are vertically stacked in sequence to form a vertical structure, and the power device 3, the PCB component 2 and the external circuit board 9 are arranged from top to bottom. For forming the vertical structure, the placement order in which the power device 3, the PCB component 2 and the external circuit board 9 are provided can be adjusted according to the practical requirements. That is, in an embodiment, the power device 3 is placed on the PCB component 2 first, and then the power device 3 and the PCB component 2 are placed on the external circuit board 9 together. Alternatively, in another embodiment, the PCB component 2 is placed on the external circuit board 9 first, and then the power device 3 is placed on the PCB component 2. In the embodiment, the lower welding position 104 of the PCB component 2 is aligned to the welding region 91 of the external circuit board 9, and the welding pad 31 of the power device 3 is aligned to the upper welding position 103 of the PCB component 2. Finally, one reflow welding process is performed according to a step S05 to achieve electrical connections between the power device 3 and the PCB component 2 and between the PCB component 2 and the external circuit board 9.

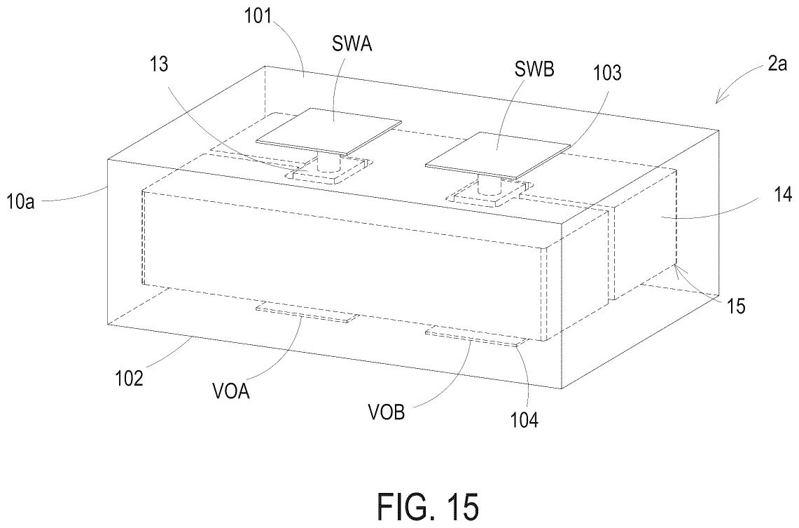

FIG. 15 is a schematic diagram illustrating a PCB component according to another embodiment of the present disclosure. Notably, for assembling the voltage regulator module 1, the present disclosure not only provides the PCB component 2 with the structure shown in FIG. 12 and FIG. 13, but also provides the PCB component 2a with the structure shown in FIG. 15. The PCB component 2a includes a multi-layer board structure 10a, and further includes an inductor 15 embedded in the multi-layer board structure 10a. The inductor 15 includes a magnetic core 14 and at least one winding 13. The magnetic core 14 is processed and formed in advance, and the winding 13 runs through the magnetic core 14 and is embedded in the multilayer board structure 10a of the PCB component 2a to form the upper and lower outlet terminals of the inductor 15. The upper and lower outlet terminals of the winding 13 of the inductor 15 are electrically connected to the upper welding position 103 and the lower welding position 104 on the surface of the PCB component 2a by electroplating drilling. Thereby, the first winding upper welding position SWA, the second winding upper welding position SWB, the first output welding position VOA and the second output welding position VOB for the two windings 13 of the inductor 15 are formed. Since the inductor 15 is built into the multi-layer board structure 10a of the PCB component 2a, and the inductor 15 and the multi-layer board structure 10a of the PCB component 2a are formed into a unified piece through the electroplating process, the unified PCB component 2a, the power device 3 and the external circuit board 9 can complete the entire welding process through only one reflow welding. Thereby, the welding reliability of the voltage regulator module 1 is improved and the production cost is reduced at the same time.

Please refer to FIG. 3 to FIG. 15. In other embodiments of the present disclosure, one PCB component 2, 2a further includes a plurality of inductors 15 connected in parallel, and the power device 3 a plurality of power devices 3. In the step 04, the solder is placed on the welding region 91 of the external circuit board 9 and the upper welding positions 103 of the plurality of inductors 15, and then the plurality of power devices 3, the PCB component 2, 2a and the external circuit board 9 are stacked in sequence vertically. In the embodiment, the welding portions of the plurality of power devices 3 are aligned to the upper welding positions 103 of the plurality of inductors 15, and the lower welding positions 104 of the plurality of inductors 15 are aligned to the welding region 91. Finally, one reflow welding process is performed according to step S05 to achieve electrical connections between the plurality of power devices 3 and the PCB component 2, 2a and between the PCB component 2, 2a and the external circuit board 9.

Please refer to FIG. 3 to FIG. 14. Regarding the above-mentioned method for manufacturing the voltage regulator module through one-time reflow welding, in some other embodiments of the present disclosure, a plurality of PCB components 2 are firstly arranged in an array on a fixing jig. Then, the solder is placed on the upper welding positions 103 on the top surfaces 101 of the plurality of PCB components by printing or spraying process. Thereafter, the plurality of PCB components 2 with the solder set are placed on the welding regions 91 of a plurality of the external circuit boards 9 in a side clamping manner, and the solder paste has been applied to the welding regions 91 by printing or spraying. Then, the power devices 3 such as the IC devices are placed on the upper welding positions 103 on the top surfaces 101 of the plurality of PCB components 2. In other embodiments, a plurality of PCB components 2 are firstly arranged in an array on a fixing jig, and then the solder is placed on the upper welding positions 103 on the top surfaces 101 of the plurality of PCB components by printing or spraying process. Thereafter, a plurality of power devices 3 such as the IC devices are placed on the upper welding positions 103 with the solder set on the top surfaces 101 of the plurality of PCB components 2. Then, the plurality of PCB components 2 with the plurality of power devices 3 set are placed on the welding regions 91 of a plurality of the external circuit boards 9 in a side clamping manner, and the solder paste has been applied to the welding regions 91 by printing or spraying. Finally, one reflow welding process is performed, and the electrical connections between the plurality of power devices 3, the PCB components 2 and between the PCB components 2 and the external circuit boards 9 are achieved.

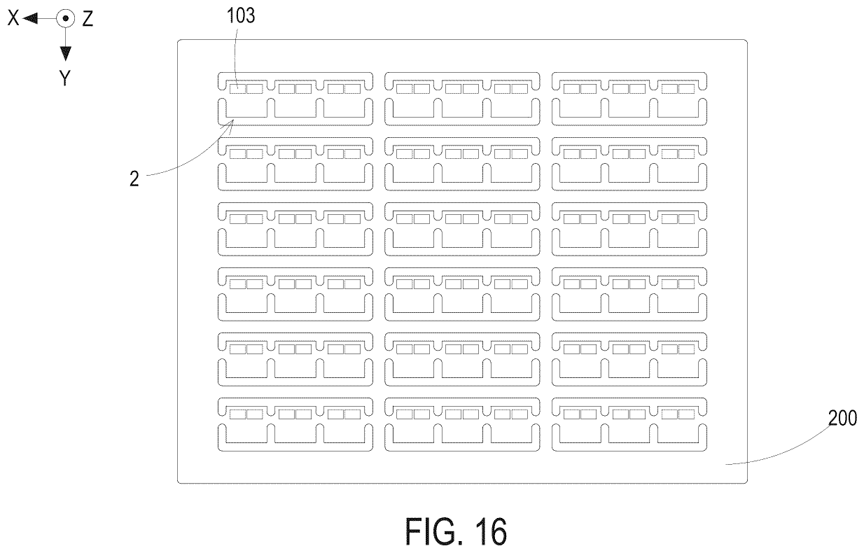

FIG. 16 is a schematic diagram illustrating a plurality of PCB components combined to form a contiguous structure according to an embodiment of the present disclosure. Please refer to FIG. 3 to FIG. 14 and FIG. 16. Regarding the above-mentioned method for manufacturing the voltage regulator module through one-time reflow welding, in some other embodiments of the present disclosure, a contiguous structure 200 including a plurality of the PCB components 2 is provided. In order to produce the voltage regulator module 1 through one single reflow welding process, the solder is firstly placed on the upper welding positions 103 of the plurality of PCB components 2 of the contiguous structure 200. Then, the contiguous structure 200 is placed on the welding regions 91 of a plurality of the external circuit boards 9 with the solder in a side clamping manner. Thereafter, a plurality of the power devices 3 are placed correspondingly on the upper welding positions 103 of the plurality of PCB components 2 of the contiguous structure 200. In other embodiments, the solder paste is firstly placed on the upper welding positions 103 of the plurality of PCB components 2 of the contiguous structure 200 by printing or spraying, and then the plurality of power devices 3 are placed on the upper welding positions 103 of the plurality of PCB components 2 of the contiguous structure 200 with solder paste set. Thereafter, the contiguous structure 200 with the plurality of power devices 3 set thereon is placed on the welding regions 91 of a plurality of the external circuit boards 9 with the solder in a side clamping manner. Then, one reflow welding process is performed to achieve the electrical connections between the plurality of power devices 3 and the contiguous structure 200 and between the contiguous structure 200 and the plurality of external circuit boards 9. Finally, the contiguous structure 200 is cut and separated, so that the plurality of power devices 3, the contiguous structure 200 and the plurality of external circuit boards 9 vertically stacked in sequence form a plurality of the voltage regulator modules 1 each independently.

Furthermore, in addition to the contiguous structure 200 formed by arranging the plurality of PCB components 2, in some other embodiments of the present disclosure, a substrate structure formed by arranging a plurality of external circuit boards 9 is provided. Regarding the above-mentioned method for manufacturing the voltage regulator module through one-time reflow welding, the solder is placed on the upper welding positions 103 of the plurality of PCB components 2 of the contiguous structure 200. Thereafter, the contiguous structure 200 is placed on the welding regions 91 of the plurality of external circuit boards 9 of the substrate structure with the solder in a side clamping manner. Then, a plurality of the power devices 3 are placed correspondingly on the upper welding positions 103 of the plurality of PCB components 2 of the contiguous structure 200. In the other embodiments, the solder paste is firstly placed on the upper welding positions 103 of the plurality of PCB components 2 of the contiguous structure 200 by printing or spraying, and then the plurality of power devices 3 are placed on the upper welding positions 103 of the plurality of PCB components 2 of the contiguous structure 200 with solder paste set. Thereafter, the contiguous structure 200 with the plurality of power devices 3 set thereon is placed on the welding regions 91 of the plurality of external circuit boards 9 of the substrate structure with the solder in a side clamping manner. Then, one reflow welding process is performed to achieve the electrical connections between the plurality of power devices 3 and the contiguous structure 200 and between the contiguous structure 200 and the substrate structure. Finally, the contiguous structure 200 and the substrate structure are cut and separated, respectively, so that the plurality of power devices 3, the contiguous structure 200 and the substrate structure vertically stacked in sequence form a plurality of the voltage regulator modules 1 each independently.

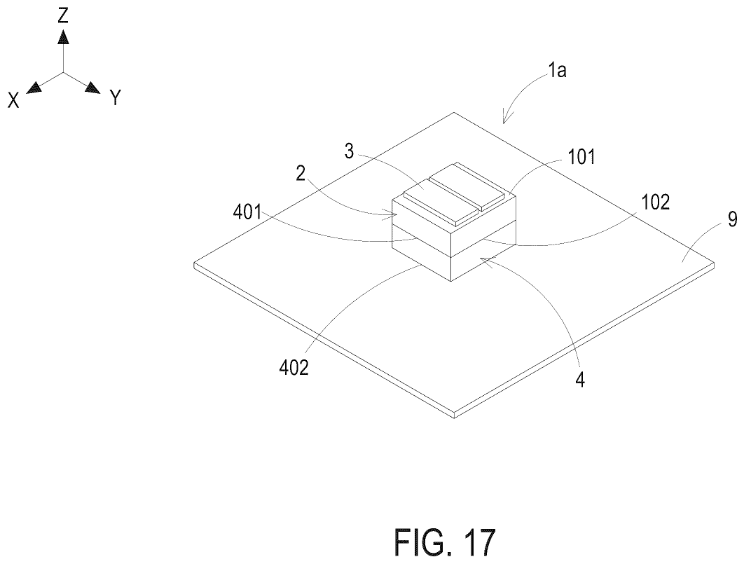

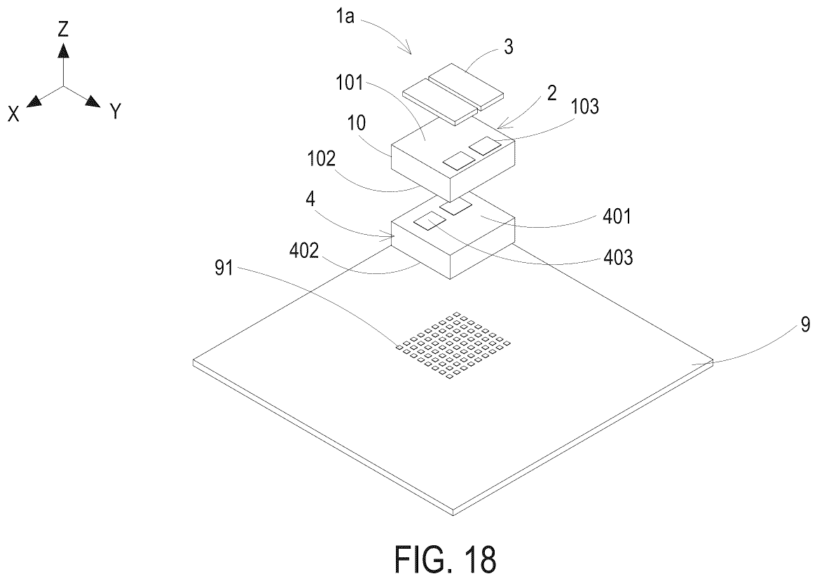

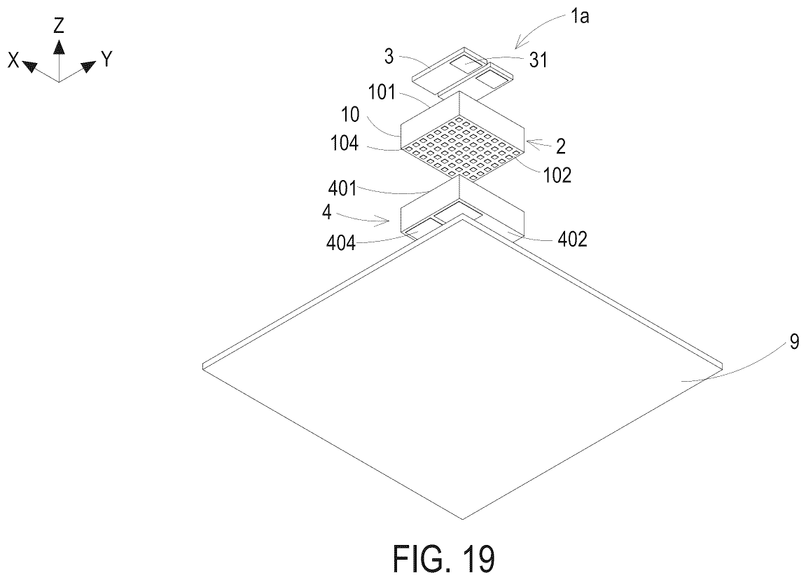

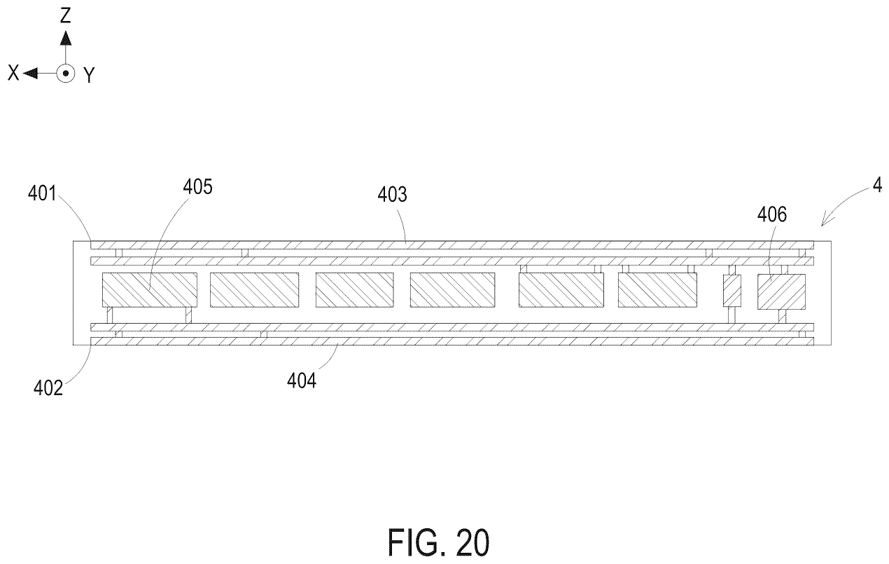

FIG. 17 is a structural perspective view illustrating a voltage regulator module with a stacked component according to a third embodiment of the present disclosure. FIG. 18 and FIG. 19 are exploded structural views illustrating the voltage regulator module according to the third embodiment of the present disclosure. FIG. 20 is a cross-sectional view illustrating the stacked component according to the third embodiment of the present disclosure. In the embodiment, the voltage regulator module 1a is similar to the voltage regulator module 1 of FIG. 1 to FIG. 13, elements with same structures and functions are denoted with same symbols, and are not redundantly described herein. In the embodiment, the voltage regulator module 1a further includes a stacked component 4 stacked between the PCB component 2 and the external circuit board 9, so that the lower welding position 104 of the PCB component is electrically connected to the external circuit board 9 via the stacked component 4. In the embodiment, the stacked component 4 includes an upper welding pad 403 and a lower welding pad 404, which are respectively disposed on the upper surface 401 and the lower surface 402 opposite to each other. In an embodiment, the stacked component 4 is a capacitor monomer, and the capacitor monomer includes a capacitor component and/or a metal conductor 406, which is embedded in the stacked component 4. In some embodiments, the capacitor component includes a plurality of capacitors 405 embedded in a circuit board (as shown in FIG. 20). In other embodiments of the present disclosure, the capacitor component is formed by welding a plurality of capacitors on the surface of the circuit board. In some embodiments, the metal conductor 406 includes a copper block, which is configured to transmit electrical signals and increase the structural strength of the stacked component 4. In other embodiments, the stacked component 4 includes a switch unit or a magnetic unit.

In the embodiment, the upper welding position 103 of the PCB component 2 is electrically connected to the power device 3, the lower welding position 104 is electrically connected to the upper welding pad 403 of the stacked component 4, and the lower welding pad 404 of the stacked component 4 is electrically connected to the welding region 91 of the external circuit board 9. The power device 3, the PCB component 2, the stacked component 4 and the external circuit board 9 are vertically stacked in sequence, and the electrical connections between the power device 3 and the upper welding position 103, between the lower welding position 104 and the upper welding pad 403, and between the lower welding pad 404 and the external circuit board 9 are implemented through one single reflow welding process to form the voltage regulator module 1a. In the embodiment, the PCB component 2, the power device 3, the stacked component 4 and the external circuit board 9 are first provided for assembly before the reflow welding process, and the placement order and the stacking order are adjustable according to the practical requirements.

In some embodiments of the present disclosure, the solder is placed on the welding region 91 of the external circuit board 9, and then the stacked component 4 is stacked on the welding region 91, so that the lower welding pad 404 of the stacked component 4 is aligned to the welding region 91. Thereafter, a solder is placed on the upper welding pad 403 of the stacked component 4, and then the PCB component 2 is stacked on the upper welding pad 403, so that the lower welding position 104 is aligned to the upper welding pad 403. Then, the solder is placed on the upper welding position 103 of the PCB component 2, and the power device 3 is stacked on the upper welding position 103, so that the welding portion of the power device 3 is aligned to the upper welding position 103. Finally, one reflow welding process is performed to achieve electrical connections between the power device 3 and the PCB component 2, between the PCB component 2 and the stacked component 4, and between the stacked component 4 and the external circuit board 9, so that the voltage regulator module 1a is formed. Certainly, the stacking order and the providing order of the power device 3, the PCB component 2, the stacked component 4 and the external circuit board 9 are adjustable according to the practical requirements but not limited to stacking in sequence. In other embodiments, the solder is placed on the upper welding pad 403 of the stacked component 4, and then the PCB component 2 is stacked on the upper welding pad 403, so that the lower welding position 104 is aligned to the upper welding pad 403. Thereafter, the solder is placed on the upper welding position 103 of the PCB component 2, and the power device 3 is stacked on the upper welding position 103, so that the welding portion of the power device 3 is aligned to the upper welding position 103. Then, the solder is placed on the welding region 91 of the external circuit board 9, and the stacked component 4 is stacked on the welding region 91. Finally, one reflow welding process is performed to achieve electrical connections between the power device 3 and the PCB component 2, between the PCB component 2 and the stacked component 4, and between the stacked component 4 and the external circuit board 9, so that the voltage regulator module 1a is formed. Certainly, some other manufacturing combinations can be flexibly adjusted according to the practical requirement and not redundantly described herein.

In some other embodiments of the present disclosure, a plurality of PCB components 2 are firstly arranged in an array on a fixing jig. Then, the solder is placed on the welding regions 91 of a plurality of external circuit boards 9, and a plurality of the stacked components are stacked on the welding regions 91 of the plurality of external circuit boards 9, so that the lower welding pads 404 of the stacked components 4 are aligned to the welding regions 91 of the plurality of external circuit boards 9. Thereafter, a solder is placed on the upper welding pads 403 of the plurality of stacked components 4, and the lower welding positions 104 of the plurality of PCB components 2 are stacked on the upper welding pads 403 of the plurality of stacked components 4 correspondingly in a side clamping manner, so that the lower welding positions 104 of the plurality of PCB components 2 are aligned to the upper welding pads 403 of the plurality of stacked components 4. Finally, the solder is placed on the upper welding positions 103 of the plurality of PCB components 2, and a plurality of the power devices 3 are stacked on the upper welding positions 103 of the PCB components 2, so that the welding portions of the plurality of power devices 3 are aligned to the upper welding positions 103 of the PCB components 2. In this way, the stacking structure of the power device 3, the PCB component 2, the stacked component 4 and the external circuit board 9 is obtained. Moreover, only one reflow welding process is needed to achieve the electrical connections between the power device 3 and the PCB component 2, between the PCB component and the stacked component 4, and between the stacked component 4 and the external circuit board 9, so that a plurality of voltage regulator modules 1a is formed. Certainly, the stacking order and the providing order of the power devices 3, the PCB components 2, the stacked components 4 and the external circuit boards 9 are adjustable according to the practical requirements but not limited to stacking in sequence. In other embodiments, the solder is placed on the upper welding pads 403 of the plurality of stacked components 4, and a plurality of PCB components 2 are arranged in an array on the fixing jig. Then, the lower welding positions 104 of the plurality of PCB components 2 are stacked on the upper welding pads 403 of the plurality of stacked components 4 correspondingly in a side clamping manner, so that the lower welding positions 104 of the plurality of PCB components 2 are aligned to the upper welding pads 403 of the plurality of stacked components 4. Thereafter, the solder is placed on the upper welding positions 103 of the plurality of PCB components 2, and a plurality of the power devices 3 are stacked on the upper welding positions 103 of the PCB components 2, so that the welding portions of the plurality of power devices 3 are aligned to the upper welding positions 103 of the PCB components 2. Finally, the solder is placed on the welding regions 91 of a plurality of external circuit boards 9, and the plurality of the stacked components 4 are stacked on the welding regions 91 of the plurality of external circuit boards 9. In this way, the stacking structure of the power device 3, the PCB component 2, the stacked component 4 and the external circuit board 9 is obtained. Moreover, only one reflow welding process is needed to achieve the electrical connections between the power device 3 and the PCB component 2, between the PCB component and the stacked component 4, and between the stacked component 4 and the external circuit board 9, so that a plurality of voltage regulator modules 1a is formed. Similarly, some other manufacturing combinations can be flexibly adjusted according to the practical requirement and not redundantly described herein.

Please refer to FIG. 16 to FIG. 20. In some other embodiments, a contiguous structure 200 including a plurality of the PCB components 2 is provided for manufacturing the voltage regulator. In order to produce the voltage regulator module 1a through one single reflow welding process, the solder is placed on the welding regions 91 of a plurality of the external circuit boards 9, and a plurality of the stacked components 4 are stacked on the welding regions 91 of the plurality of external circuit boards 9 with the solder set, so that the lower welding pads 404 of the plurality of stacked component 4 are aligned to the welding regions 91 of the plurality of external circuit boards 9. Then, a solder is placed on the upper welding pads 403 of the plurality of stacked components 4, and the lower welding positions 104 of the plurality of PCB components 2 of the contiguous structure 200 on the upper welding pads 403 of the plurality of stacked components 4 correspondingly in a side clamping manner, so that the lower welding positions 104 of the plurality of PCB components 4 of the contiguous structure 200 are aligned to the upper welding pads 403 of the plurality of stacked components 4. Thereafter, the solder is placed on the upper welding positions 103 of the plurality of PCB components 2 of the contiguous structure 200, and a plurality of the power devices 3 are stacked on the upper welding positions 103 of the PCB components 2 of the contiguous structure 200 correspondingly, so that the welding portions of the plurality of power devices 3 are aligned to the upper welding positions 103 of the PCB components 2 of the contiguous structure 200. Then, one reflow welding process is performed to achieve the electrical connections between the plurality of power devices 3 and the contiguous structure 200, between the contiguous structure 200 and the plurality of stacked components 4, and between the plurality of stacked components 4 and the plurality of external circuit boards 9. Finally, the contiguous structure 200 is cut and separated, so that the plurality of power devices 3, the contiguous structure 200, the plurality of stacked components 4 and the plurality of external circuit boards 9 vertically stacked in sequence form a plurality of the voltage regulator modules 1a each independently. Certainly, the stacking order and the providing order of the power devices 3, the contiguous structure 200, the stacked components 4 and the external circuit boards 9 are adjustable according to the practical requirements but not limited to stacking in sequence. In other embodiments, the solder is placed on the upper welding pads 403 of the plurality of stacked components 4, and the lower welding positions 104 of the plurality of PCB components 2 of the contiguous structure 200 are stacked on the upper welding pads 403 of the plurality of stacked components 4 correspondingly in a side clamping manner, so that the lower welding positions 104 of the plurality of PCB components 2 of the contiguous structure 200 are aligned to the upper welding pads 403 of the plurality of stacked components 4. Thereafter, the solder is placed on the upper welding positions 103 of the plurality of PCB components 2 of the contiguous structure 200, and a plurality of the power devices 3 are stacked on the upper welding positions 103 of the PCB components 2, so that the welding portions of the plurality of power devices 3 are aligned to the upper welding positions 103 of the PCB components 2 of the contiguous structure 200. Then, the solder is placed on the welding regions 91 of a plurality of external circuit boards 9, and the plurality of the stacked components 4 are stacked on the welding regions 91 of the plurality of external circuit boards 9, so that the lower welding pads 404 of the plurality of stacked component 4 are aligned to the welding regions 91 of the plurality of external circuit boards 9. Thereafter, one reflow welding process is performed to achieve the electrical connections between the plurality of power devices 3 and the contiguous structure 200, between the contiguous structure 200 and the plurality of stacked components 4, and between the plurality of stacked components 4 and the plurality of external circuit boards 9. Similarly, some other manufacturing combinations can be flexibly adjusted according to the practical requirement and not redundantly described herein.

Furthermore, in addition to the contiguous structure 200 formed by arranging the plurality of PCB components 2, in some other embodiments of the present disclosure, a substrate structure formed by arranging a plurality of external circuit boards 9 is provided. Regarding the above-mentioned method for manufacturing the voltage regulator module through one-time reflow welding, the solder is placed on the welding regions 91 of the plurality of external circuit boards 9 of the substrate structure, and a plurality of the stacked components 4 are stacked on the welding regions 91 of the plurality of external circuit boards 9 of the substrate structure, so that the lower welding pads 404 of the plurality of stacked component 4 are aligned to the welding regions 91 of the plurality of external circuit boards 9 of the substrate structure. Then, a solder on the upper welding pads 403 of the plurality of stacked components 4, and the lower welding positions 104 of the plurality of PCB components 2 of the contiguous structure 200 are stacked on the upper welding pads 403 of the plurality of stacked components 4 correspondingly in a side clamping manner, so that the lower welding positions 104 of the plurality of PCB components 2 of the contiguous structure 200 are aligned to the upper welding pads 403 of the plurality of stacked components 4. Thereafter, the solder is placed on the upper welding positions 103 of the plurality of PCB components 2 of the contiguous structure 200, and a plurality of the power devices 3 are stacked on the upper welding positions 103 of the PCB components 2 of the contiguous structure 200 correspondingly, so that the welding portions of the plurality of power devices 3 are aligned to the upper welding positions 103 of the PCB components 2 of the contiguous structure 200. Then, one reflow welding process is performed to achieve the electrical connections between the plurality of power devices 3 and the contiguous structure 200, between the contiguous structure 200 and the plurality of stacked components 4, and between the plurality of stacked components 4 and the substrate structure. Finally, the contiguous structure 200 and the substrate structure are cut and separated, respectively, so that the plurality of power devices 3, the contiguous structure 200, the plurality of stacked components 4 and the substrate structure vertically stacked in sequence form a plurality of the voltage regulator modules 1a each independently. Certainly, the stacking order and the providing order of the power devices 3, the contiguous structure 200, the stacked components 4 and the substrate structure are adjustable according to the practical requirements but not limited to stacking in sequence. In other embodiments, the solder is placed on the upper welding pads 403 of the plurality of stacked components 4, and the lower welding positions 104 of the plurality of PCB components 2 of the contiguous structure 200 are stacked on the upper welding pads 403 of the plurality of stacked components 4 correspondingly in a side clamping manner, so that the lower welding positions 104 of the plurality of PCB components 2 of the contiguous structure 200 are aligned to the upper welding pads 403 of the plurality of stacked components 4. Thereafter, the solder is placed on the upper welding positions 103 of the plurality of PCB components 2 of the contiguous structure 200, and a plurality of the power devices 3 are stacked on the upper welding positions 103 of the PCB components 2, so that the welding portions of the plurality of power devices 3 are aligned to the upper welding positions 103 of the PCB components 2 of the contiguous structure 200. Then, the solder is placed on the welding regions 91 of a plurality of external circuit boards 9 of the substrate structure, and the plurality of the stacked components 4 are stacked on the welding regions 91 of the plurality of external circuit boards 9 of the substrate structure, so that the lower welding pads 404 of the plurality of stacked component 4 are aligned to the welding regions 91 of the plurality of external circuit boards 9 of the substrate structure. Thereafter, one reflow welding process is performed to achieve the electrical connections between the plurality of power devices 3 and the contiguous structure 200, between the contiguous structure 200 and the plurality of stacked components 4, and between the plurality of stacked components 4 and the substrate structure. Similarly, some other manufacturing combinations can be flexibly adjusted according to the practical requirement and not redundantly described hereafter.

In summary, the present disclosure provides a PCB component used in a voltage regulator module and a method for manufacturing the voltage regulator module. By integrating an inductor, an input circuit path, a control signal path, a signal detection path and a test function circuit into a PCB component, the number of stacked layers of the voltage regulator module is simplified. Thereby, the total number of welding times of the product is greatly reduced, the production cost of the voltage regulator module is reduced, and the product quality is improved. One layer of the voltage regulator module is a PCB component with an embedded inductor, and the layer above the PCB component can be used to place the power device. In the inductor integrated in the PCB component, the inductor winding runs through the inside of the magnetic core and is embedded in the PCB component. The two output terminals of the inductor winding are integrated with the circuit-board copper in the PCB component through the electroplating process. The electroplated copper is interconnected from the inside to the outside, and pressed together successively to form the welding position for the IC power device on the outer layer of the PCB component. The number of electroplated copper layers stacked on both sides of the inductor is symmetrical and equal. Since the power device, the PCB component, the stacked component and the external circuit board are connected in an up-and-down stacking manner, it facilitates to reduce the total occupied area of the voltage regulator module. At the same time, the welding of the entire voltage regulator can be completed with only one reflow welding, so that the module production yield is increased and the production cost is reduced. At the same time, the PCB component can coordinate with the power devices, external circuit boards and stacked parts to adjust the placement order when stacking, so that the voltage regulator module can be flexibly adjusted according to actual conditions during manufacturing, which is easy to manufacture. Furthermore, the PCB component, the power device, the external circuit board and the stacked component are coordinated with each other and allowed adjusting the placement order when stacking, so that the manufacturing process of the voltage regulator module is flexibly adjustable according to the practical conditions, and it is easy to manufacture. On the other hand, when the PCB component is used in the manufacture of the voltage regulator module, it can further combine a contiguous structure of multiple PCB components and a substrate structure of multiple external circuit boards. In that, multiple voltage regulator modules can be manufactured with only one reflow welding process. After cutting and separation, a plurality of voltage regulator modules are obtained and independent with each other. Thereby the product quality and the long-term reliability are improved, and the production costs are greatly reduced. Alternatively, by placing the multiple PCB components on an assembling jig, the multiple voltage regulator modules can be manufactured with only one reflow welding process.

It is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A PCB component, comprising:
a PCB, wherein the PCB comprises a top surface and a bottom surface opposite to each other; and
an inductor, wherein the inductor comprises an upper surface and a lower surface opposite to each other, the inductor further comprises a magnetic core and a winding, the winding runs through the magnetic core, and the winding forms an upper outlet terminal on the upper surface and a lower outlet terminal on the lower surface;
wherein the inductor is embedded in the PCB, the top surface is spatially corresponding to the upper surface, the bottom surface is spatially corresponding to the lower surface, a plurality of conductive layers are respectively disposed above the upper surface and below the lower surface, an upper welding position is disposed on the top surface and electrically connected to the upper outlet terminal, and a lower welding position is disposed on the bottom surface and electrically connected to the lower outlet terminal;
wherein the upper welding position is electrically connected to a power device and configured to transmit an input electrical signal, the lower welding position is electrically connected to an external circuit board and configured to transmit an output electrical signal, and the power device, the PCB component and the external circuit board are stacked vertically in sequence, wherein electrical connections between the power device and the upper welding position, and between the lower welding position and the external circuit board are implemented through one reflow welding process to form a voltage regulator module.

2. The PCB component according to claim 1, wherein the PCB component comprises a plurality of PCB components, the power device comprises a plurality of power devices, the external circuit board comprises a plurality of external circuit boards, the plurality of PCB components are arrayed on a fixing jig, the plurality of power devices, the plurality of PCB components and the plurality of external circuit boards are vertically stacked in sequence, and electrical connections between the plurality of power devices and the upper welding positions of the plurality of PCB components and between the plurality of lower welding positions of the plurality of PCB components and the plurality of external circuit boards are implemented through one reflow welding process to form a plurality of the voltage regulator modules.

3. The PCB component according to claim 1, wherein the PCB component comprises a plurality of PCB components, the power device comprises a plurality of power devices, the external circuit board comprises a plurality of external circuit boards, the plurality of PCB components are combined to form a contiguous structure, the plurality of power devices, the contiguous structure and the plurality of external circuit boards are vertically stacked in sequence, and electrical connections between the plurality of power devices and the upper welding positions of the plurality of PCB components of the contiguous structure and between the plurality of lower welding positions of the plurality of PCB components of the contiguous structure and the plurality of external circuit boards are implemented through one reflow welding process, wherein the contiguous structure is separated by cutting, so that the plurality of power devices, the contiguous structure and the plurality of external circuit boards vertically stacked form a plurality of the voltage regulator modules each independently.

4. The PCB component according to claim 1, wherein the PCB component comprises a plurality of PCB components, the power device comprises a plurality of power devices, the external circuit board comprises a plurality of external circuit boards, the plurality of PCB components are combined to form a contiguous structure, the plurality of external circuit boards are combined to form a substrate structure, the plurality of power devices, the contiguous structure and the substrate structure are vertically stacked in sequence, and electrical connections between the plurality of power devices and the upper welding positions of the plurality of PCB components of the contiguous structure and between the plurality of lower welding positions of the plurality of PCB components of the contiguous structure and the plurality of external circuit boards of the substrate structure are implemented through one reflow welding process, wherein the contiguous structure and the substrate structure are respectively separated by cutting, so that the plurality of power devices, the contiguous structure and the substrate structure vertically stacked form a plurality of the voltage regulator modules each independently.

5. The PCB component according to claim 1, wherein the PCB component comprises a plurality of inductors connected in parallel, wherein the upper welding positions of the plurality of inductors are electrically connected to a plurality of the power devices, respectively, and configured to transmit the input electrical signal, and the lower welding positions of the plurality of inductors are electrically connected to the external circuit board and configured to transmit the output electrical signal, wherein the plurality of power devices, the PCB component and the external circuit board are vertically stacked in sequence, and electrical connections between the plurality of power devices and the upper welding positions of the plurality of inductors and between the lower welding positions of the plurality of inductors and the external circuit board are implemented connected through one reflow welding process to form the voltage regulator module.

6. The PCB component according to claim 1, wherein a volume proportion of the magnetic core in the PCB component exceeds 50%, and in a horizontal plane, a projected area of the magnetic core exceeds more than 70% of a projected area of the PCB component.

7. The PCB component according to claim 1, wherein the PCB component further comprises an input circuit path, a control signal path, a signal detection path or a test function circuit.

8. The PCB component according to claim 1, wherein a metal conductor is further disposed inside the PCB component, and the metal conductor is configured to transmit an electrical signal.

9. The PCB component according to claim 1, wherein the lower welding position and the external circuit board are electrically connected via a stacked component, and the stacked component comprises an upper welding pad and a lower welding pad.

10. The PCB component according to claim 9, wherein the stacked component is a capacitor monomer, a switch monomer or a magnetic component monomer.

11. The PCB component according to claim 9, wherein a metal conductor is disposed inside the stacked component, and the metal conductor is configured to transmit an electrical signal.

12. The PCB component according to claim 9, wherein the upper welding position is electrically connected to the power device, the lower welding position is electrically connected to the upper welding pad, and the lower welding pad is electrically connected to the external circuit board, wherein the power device, the PCB component, the stacked component and the external circuit board are vertically stacked in sequence, and electrical connections between the power device and the upper welding position, between the lower welding position and the upper welding pad, and between the lower welding pad and the external circuit board are implemented through one reflow welding process to form the voltage regulator module.

13. The PCB component according to claim 9, wherein the PCB component comprises a plurality of PCB components, the power device comprises a plurality of power devices, the stacked component comprises a plurality of stacked components, the external circuit board comprises a plurality of external circuit boards, the plurality of PCB components are arrayed on a fixing jig, the plurality of power devices, the plurality of PCB components, the plurality of stacked components and the plurality of external circuit boards are vertically stacked in sequence, and electrical connections between the plurality of power devices and the upper welding positions of the plurality of PCB components, between the plurality of lower welding positions of the plurality of PCB components and the upper welding pads of the plurality of stacked components, and between the lower welding pads of the plurality of stacked components and the plurality of external circuit boards are implemented through one reflow welding process to form a plurality of the voltage regulator modules.

14. The PCB component according to claim 9, wherein the PCB component comprises a plurality of PCB components, the power device comprises a plurality of power devices, the stacked component comprises a plurality of stacked components, the external circuit board comprises a plurality of external circuit boards, the plurality of PCB components are combined to form a contiguous structure, the plurality of power devices, the contiguous structure, the plurality of stacked components and the plurality of external circuit boards are vertically stacked in sequence, and electrical connections between the plurality of power devices and the upper welding positions of the plurality of PCB components of the contiguous structure, between the plurality of lower welding positions of the plurality of PCB components of the contiguous structure and the upper welding pads of the plurality of stacked components, and between the lower welding pads of the plurality of stacked components and the plurality of external circuit boards are implemented through one reflow welding process, wherein the contiguous structure is separated by cutting, so that the plurality of power devices, the contiguous structure, the plurality of stacked components and the plurality of external circuit boards vertically stacked form a plurality of the voltage regulator modules each independently.

15. The PCB component according to claim 9, wherein the PCB component comprises a plurality of PCB components, the power device comprises a plurality of power devices, the stacked component comprises a plurality of stacked components, the external circuit board comprises a plurality of external circuit boards, the plurality of PCB components are combined to form a contiguous structure, the plurality of external circuit boards are combined to form a substrate structure, the plurality of power devices, the contiguous structure, the plurality of stacked components and the substrate structure are vertically stacked in sequence, and electrical connections between the plurality of power devices and the upper welding positions of the plurality of PCB components of the contiguous structure, between the plurality of lower welding positions of the plurality of PCB components of the contiguous structure and the upper welding pads of the plurality of stacked components, and between the lower welding pads of the plurality of stacked components and the plurality of external circuit boards of the substrate structure are implemented through one reflow welding process, wherein the contiguous structure are respectively separated by cutting, so that the plurality of power devices, the contiguous structure, the plurality of stacked components and the substrate structure vertically stacked form a plurality of the voltage regulator modules each independently.

16. The PCB component according to claim 1, wherein the PCB comprises M conductive layers and N conductive layers, M and N are positive integers, the M conductive layers are arranged above the upper surface, the upper outlet terminal is electrically connected to one of the M conductive layers attached to the upper surface, the N conductive layers are arranged below the lower surface, the lower outlet terminal is electrically connected to one of the N conductive layers attached to the lower surface, and M=N≥2.

17. The PCB component according to claim 16, wherein the M conductive layers and the N conductive layers respectively include a surface conductive layer and an inner conductive layer, wherein the surface conductive layer includes the top surface and the bottom surface for surface wiring, copper cladding and device welding, and the inner conductive layer is used for internal wiring and copper cladding.

18. The PCB component according to claim 16, wherein the M conductive layers and the N conductive layers are respectively composed of a plurality of copper plating layers.

19. The PCB component according to claim 16, further comprising a board-edge copper-plating layer, wherein the board-edge copper-plating layer is disposed on the top surface, the bottom surface and one side wall of the PCB, electrically connected between the M conductive layers and the N conductive layers, and configured to transmit current signals or form a test function circuit.

20. The PCB component according to claim 16, further comprising a conductive through hole, wherein the conductive through hole runs through the top surface and the bottom surface and is electrically connected between the M conductive layers and the N conductive layers.

21. The PCB component according to claim 16, wherein each adjacent two of the M conductive layers and the N conductive layers are connected via a buried via, and the M conductive layers and the N conductive layers are electrically connected to an external electrical signal from the inside to the outside through the buried via sequentially.

22. The PCB component according to claim 21, wherein the N conductive layers form output welding position and ground welding positions on the bottom surface through the buried via, wherein the output welding positions and the ground welding positions are arranged alternately.

23. The PCB component according to claim 16, wherein the upper welding position and the upper outlet terminal are spatially corresponding to each other and electrically connected through an upper circuit channel, and the upper circuit channel is electrically connected to the M conductive layers in sequence.

24. The PCB component according to claim 16, wherein the lower welding position and the lower outlet terminal are spatially corresponding to each other and electrically connected via a lower circuit channel, and the lower circuit channel is electrically connected to the N conductive layers in sequence.

25. The PCB component according to claim 24, wherein the upper circuit channel is electrically connected to the upper welding position and the upper outlet terminal through copper-electroplated holes in the M conductive layers from the inside to the outside, and the lower circuit channel is electrically connected to the lower welding position and the lower outlet terminal through copper-electroplated holes in the N conductive layers from the inside to the outside.

26. A method for manufacturing a voltage regulator module, comprising steps of:
(a) providing a PCB component, wherein the PCB component comprises a PCB and an inductor, wherein the PCB comprises a top surface and a bottom surface opposite to each other, the inductor comprises an upper surface and a lower surface opposite to each other, the top surface is spatially corresponding to the upper surface, the bottom surface is spatially corresponding to the lower surface, the inductor is embedded in the PCB, the inductor comprises a magnetic core and a winding, the winding runs through the magnetic core, and the winding forms an upper outlet terminal on the upper surface and a lower outlet terminal on the lower surface, wherein a plurality of conductive layers are respectively disposed above the upper surface and below the lower surface, an upper welding position is disposed on the top surface and electrically connected to the upper outlet terminal, and a lower welding position is disposed on the bottom surface and electrically connected to the lower outlet terminal;
(b) providing a power device, comprising a welding portion spatially corresponding to the upper welding position;
(c) providing an external circuit board, comprising a welding region spatially corresponding to the lower welding position;
(d) placing a solder on the welding region and the upper welding position, and stacking the power device, the PCB component and the external circuit board in sequence vertically, wherein the welding portion is aligned to the upper welding position, and the lower welding position is aligned to the welding region; and
(e) performing one reflow welding process to achieve electrical connections between the power device and the PCB component and between the PCB component and the external circuit board.

27. The method for manufacturing the voltage regulator module according to claim 26, wherein a volume proportion of the magnetic core in the PCB component exceeds 50%, and in a horizontal plane, a projected area of the magnetic core exceeds more than 70% of a projected area of the PCB component.

28. The method for manufacturing the voltage regulator module according to claim 26, wherein the solder is a solder paste, and the solder is applied by spraying or printing.

29. The method for manufacturing the voltage regulator module according to claim 26, wherein the PCB component further comprises an input circuit path, a control signal path, a signal detection path or a test function circuit integrated therein.

30. The method for manufacturing the voltage regulator module according to claim 26, wherein a metal conductor is further disposed inside the PCB component, and the metal conductor is configured to transmit an electrical signal.

31. The method for manufacturing the voltage regulator module according to claim 26, wherein the PCB component comprises a plurality of inductors connected in parallel, the power device comprises a plurality of power devices, and the step (d) further comprises a step of: placing the solder on the welding region and the upper welding positions of the plurality of inductors, and stacking the plurality of power devices, the PCB component and the external circuit board in sequence vertically, wherein the welding portions of the plurality of power devices are aligned to the upper welding positions of the plurality of inductors, and the lower welding positions of the plurality of inductors are aligned to the welding region.

32. The method for manufacturing the voltage regulator module according to claim 26, wherein the step (d) further comprises:
arranging a plurality of the PCB components in an array on a fixing jig;
placing the solder on the upper welding positions of the plurality of PCB components;
placing the plurality of PCB components on the welding regions of a plurality of the external circuit boards with the solder in a side clamping manner; and
placing a plurality of the power devices correspondingly on the upper welding positions of the plurality of PCB components.

33. The method for manufacturing the voltage regulator module according to claim 26, wherein the step (d) further comprises:
providing a contiguous structure, wherein the contiguous structure comprises a plurality of the PCB components;
placing the solder on the upper welding positions of the plurality of PCB components of the contiguous structure;
placing the contiguous structure on the welding regions of a plurality of the external circuit boards with the solder in a side clamping manner; and
placing a plurality of the power devices correspondingly on the upper welding positions of the plurality of PCB components of the contiguous structure.

34. The method for manufacturing the voltage regulator module according to claim 33, wherein the step (e) further comprises sub-steps of:
(e1) performing one reflow welding process to achieve the electrical connections between the plurality of power devices and the contiguous structure and between the contiguous structure and the plurality of external circuit boards; and
(e2) cutting and separating the contiguous structure, so that the plurality of power devices, the contiguous structure and the plurality of external circuit boards vertically stacked in sequence form a plurality of the voltage regulator modules each independently.

35. The method for manufacturing the voltage regulator module according to claim 26, wherein the step (d) further comprises:
providing a contiguous structure, wherein the contiguous structure comprises a plurality of the PCB components;
providing a substrate structure, wherein the substrate structure comprises a plurality of the external circuit boards;
placing the solder on the upper welding positions of the plurality of PCB components of the contiguous structure;
placing the contiguous structure on the welding regions of the plurality of external circuit boards of the substrate structure with the solder in a side clamping manner; and
placing a plurality of the power devices correspondingly on the upper welding positions of the plurality of PCB components of the contiguous structure.

36. The method for manufacturing the voltage regulator module according to claim 35, wherein the step (e) further comprises sub-steps of:
(e1) performing one reflow welding process to achieve the electrical connections between the plurality of power devices and the contiguous structure and between the contiguous structure and the substrate structure; and
(e2) cutting and separating the contiguous structure and the substrate structure, respectively, so that the plurality of power devices, the contiguous structure and the substrate structure vertically stacked in sequence form a plurality of the voltage regulator modules each independently.

37. The method for manufacturing the voltage regulator module according to claim 26, wherein the lower welding position and the external circuit board are electrically connected via a stacked component, and the stacked component comprises an upper welding pad and a lower welding pad.

38. The method for manufacturing the voltage regulator module according to claim 37, wherein the stacked component is a capacitor monomer, a switch monomer or a magnetic component monomer.

39. The method for manufacturing the voltage regulator module according to claim 37, wherein a metal conductor is disposed inside the stacked component, and the metal conductor is configured to transmit an electrical signal.

40. The method for manufacturing the voltage regulator module according to claim 37, wherein the step (d) further comprises:
placing the solder on the welding region and stacking the stacked component on the welding region, so that the lower welding pad is aligned to the welding region;
placing a solder on the upper welding pad, and stacking the PCB component on the upper welding pad, so that the lower welding position is aligned to the upper welding pad; and
placing the solder on the upper welding position, and stacking the power device on the upper welding position, so that the welding portion is aligned to the upper welding position.

41. The method for manufacturing the voltage regulator module according to claim 37, wherein the step (d) further comprises:
arranging a plurality of the PCB components in an array on a fixing jig;
placing the solder on the welding regions of a plurality of the external circuit boards and stacking a plurality of the stacked components on the welding regions of the plurality of external circuit boards, so that the lower welding pads of the stacked components are aligned to the welding regions of the plurality of external circuit boards;
placing a solder on the upper welding pads of the plurality of stacked components, and stacking the lower welding positions of the plurality of PCB components on the upper welding pads of the plurality of stacked components correspondingly in a side clamping manner, so that the lower welding positions of the plurality of PCB components are aligned to the upper welding pads of the plurality of stacked components; and
placing the solder on the upper welding positions of the plurality of PCB components, and stacking a plurality of the power devices on the upper welding positions of the PCB components, so that the welding portions of the plurality of power devices are aligned to the upper welding positions of the PCB components.

42. The method for manufacturing the voltage regulator module according to claim 37, wherein the step (d) further comprises:
providing a contiguous structure, wherein the contiguous structure comprises a plurality of the PCB components;
placing the solder on the welding regions of a plurality of the external circuit boards, and stacking a plurality of the stacked components on the welding regions of the plurality of external circuit boards;
placing a solder on the upper welding pads of the plurality of stacked components, and stacking the lower welding positions of the plurality of PCB components of the contiguous structure on the upper welding pads of the plurality of stacked components correspondingly in a side clamping manner, so that the lower welding positions of the plurality of PCB components of the contiguous structure are aligned to the upper welding pads of the plurality of stacked components; and
placing the solder on the upper welding positions of the plurality of PCB components of the contiguous structure, and stacking a plurality of the power devices on the upper welding positions of the PCB components of the contiguous structure correspondingly, so that the welding portions of the plurality of power devices are aligned to the upper welding positions of the PCB components of the contiguous structure.

43. The method for manufacturing the voltage regulator module according to claim 42, wherein the step (e) further comprises sub-steps of:
(e1) performing one reflow welding process to achieve the electrical connections between the plurality of power devices and the contiguous structure, between the contiguous structure and the plurality of stacked components, and between the plurality of stacked components and the plurality of external circuit boards; and
(e2) cutting and separating the contiguous structure, so that the plurality of power devices, the contiguous structure, the plurality of stacked components and the plurality of external circuit boards vertically stacked in sequence form a plurality of the voltage regulator modules each independently.

44. The method for manufacturing the voltage regulator module according to claim 37, wherein the step (d) further comprises:
providing a contiguous structure, wherein the contiguous structure comprises a plurality of the PCB components;
providing a substrate structure, wherein the substrate structure comprises a plurality of the external circuit boards;
placing the solder on the welding regions of the plurality of external circuit boards of the substrate structure, and stacking a plurality of the stacked components on the welding regions of the plurality of external circuit boards of the substrate structure;
placing a solder on the upper welding pads of the plurality of stacked components, and stacking the lower welding positions of the plurality of PCB components of the contiguous structure on the upper welding pads of the plurality of stacked components correspondingly in a side clamping manner, so that the lower welding positions of the plurality of PCB components of the contiguous structure are aligned to the upper welding pads of the plurality of stacked components; and
placing the solder on the upper welding positions of the plurality of PCB components of the contiguous structure, and stacking a plurality of the power devices on the upper welding positions of the PCB components of the contiguous structure correspondingly, so that the welding portions of the plurality of power devices are aligned to the upper welding positions of the PCB components of the contiguous structure.

45. The method for manufacturing the voltage regulator module according to claim 44, wherein the step (e) further comprises sub-steps of:
(e1) performing one reflow welding process to achieve the electrical connections between the plurality of power devices and the contiguous structure, between the contiguous structure and the plurality of stacked components, and between the plurality of stacked components and the substrate structure; and
(e2) cutting and separating the contiguous structure and the substrate structure, respectively, so that the plurality of power devices, the contiguous structure, the plurality of stacked components and the substrate structure vertically stacked in sequence form a plurality of the voltage regulator modules each independently.

46. The method for manufacturing the voltage regulator module according to claim 26, wherein the PCB comprises M conductive layers and N conductive layers, M and N are positive integers, the M conductive layers are arranged above the upper surface, the upper outlet terminal is electrically connected to one of the M conductive layers attached to the upper surface, the N conductive layers are arranged below the lower surface, the lower outlet terminal is electrically connected to one of the N conductive layers attached to the lower surface, and M=N≥2.

47. The method for manufacturing the voltage regulator module according to claim 46, wherein the M conductive layers and the N conductive layers respectively include a surface conductive layer and an inner conductive layer, wherein the surface conductive layer includes the top surface and the bottom surface for surface wiring, copper cladding and device welding, and the inner conductive layer is used for internal wiring and copper cladding.

48. The method for manufacturing the voltage regulator module according to claim 46, wherein the M conductive layers and the N conductive layers are respectively composed of a plurality of copper plating layers.

49. The method for manufacturing the voltage regulator module according to claim 46, wherein the PCB component further comprises a board-edge copper-plating layer, wherein the board-edge copper-plating layer is disposed on the top surface, the bottom surface and one side wall of the PCB, electrically connected between the M conductive layers and the N conductive layers, and configured to transmit current signals or form a test function circuit.

50. The method for manufacturing the voltage regulator module according to claim 46, wherein the PCB component further comprises a conductive through hole, wherein the conductive through hole runs through the top surface and the bottom surface and is electrically connected between the M conductive layers and the N conductive layers.

51. The method for manufacturing the voltage regulator module according to claim 46, wherein the upper welding position and the upper outlet terminal are spatially corresponding to each other and electrically connected through an upper circuit channel, and the upper circuit channel is electrically connected to the M conductive layers in sequence, wherein the lower welding position and the lower outlet terminal are spatially corresponding to each other and electrically connected via a lower circuit channel, and the lower circuit channel is electrically connected to the N conductive layers in sequence.

52. The method for manufacturing the voltage regulator module according to claim 51, wherein the upper circuit channel is electrically connected to the upper welding position and the upper outlet terminal through copper-electroplated holes in the M conductive layers from the inside to the outside, and the lower circuit channel is electrically connected to the lower welding position and the lower outlet terminal through copper-electroplated holes in the N conductive layers from the inside to the outside.
